(19) United States
(12) Patent Application Publication
(10) Pub. No.: US 2025/0211179 A1
(43) Pub. Date: Jun. 26, 2025

(54) CONFIGURABLE LOW NOISE AMPLIFIER INPUT MATCHING NETWORK

(71) Applicant: QUALCOMM Incorporated, San Diego, CA (US)

(72) Inventors: Jouni Kristian KAUKOVUORI, Vantaa (FI); Mikko KALTIOKALLIO, Espoo (FI); Tero TIKKA, Espoo (FI)

(21) Appl. No.: 18/396,101

(22) Filed: Dec. 26, 2023

(51) Int. Cl. H03F 1/56; H03F 3/72

(52) U.S. Cl. CPC H03F 1/565; H03F 3/72; H03F 2200/294; H03F 2200/451; H03F 2203/7209

(57) ABSTRACT

An apparatus includes a first plurality of switches having a first plurality of input nodes and a first common output node, a second plurality of switches having a second plurality of input nodes and a second common output node, a low noise amplifier having a low noise amplifier input node and a low noise amplifier output node, a first matching component having a first node coupled to the first common output node and a second node coupled to the low noise amplifier input node, and a second matching component having a third node coupled to the second common output node and fourth node coupled to the first common output node and the first node, where at least two matching network configurations of the first matching component and the second matching component are obtained by configuring respective states of the first plurality of switches and the second plurality of switches.

### TECHNICAL FIELD

Aspects of the present disclosure generally relate to wireless communication user equipment and, more particularly, to configurable low noise amplifier input matching networks utilized in such user equipment.

### INTRODUCTION

Most communication devices receive signals on a plurality of channels. A center frequency and a channel bandwidth may specify each channel. The channels may or may not be contiguous to each other. The receiver of the communication device may be tuned to a desired channel (e.g., a local oscillator of the receiver may be tuned such that a center frequency of the desired channel is down converted to an intermediate frequency (IF) or to a baseband frequency for signal processing). The communication device may include a preselector between an antenna and a low noise amplifier (LNA) of the communication device. The preselector may suppress signals of undesired channels from the signal of a desired channel. The preselector may include a plurality of bandpass filters; each tuned to a respective center frequency and bandwidth of one of the plurality of channels that the communication device may receive. In response to being configured to receive a given channel of the plurality of channels, the preselector may be configured to apply all signals received at the antenna to the bandpass filter corresponding to the given channel. The bandpass filter passes the desired channel and filters out (e.g., suppresses) the undesired channels.

An output of the preselector may be coupled to an input of the LNA via a matching network. The LNA may have a wide bandwidth, sufficient to amplify all channels that the communication device may receive. The input impedance of the LNA may vary across the LNA's bandwidth. The matching network may be required because the input impedance of the LNA at a given channel's center frequency and over the given channel's bandwidth (where the bandwidth of the LNA is greater than the given channel's bandwidth) may not match the output impedance of a bandpass filter in the preselector that is configured to pass the given channel across the given channel's bandwidth. Scientists and engineers continue to search for ways to reduce the impedance mismatch between a preselector's output and an LNA's input.

### BRIEF SUMMARY OF SOME EXAMPLES

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

In one example, an apparatus is described. The apparatus includes a first plurality of switches having a respective first plurality of input nodes and a first common output node, a second plurality of switches having a respective second plurality of input nodes and a second common output node, a low noise amplifier having a low noise amplifier input node and a low noise amplifier output node, a first matching component having a first node coupled to the first common output node and having a second node coupled to the low noise amplifier input node, and a second matching component having a third node coupled to the second common output node and having fourth node coupled to the first common output node and the first node, where at least two matching network configurations of the first matching component and the second matching component are obtained by configuring respective states of the first plurality of switches and the second plurality of switches.

In another example, a method at an apparatus is described. The method includes configuring a first plurality of switches coupled between respective ones of a first plurality of input nodes and a first common output node to either: a first state in which a first switch of the first plurality of switches is closed and remaining switches of the first plurality of switches are open, or a second state in which each of the first plurality of switches are open; and configuring a second plurality of switches coupled between respective ones of a second plurality of input nodes and a second common output node to either: a third state in which a second switch of the second plurality of switches is closed and remaining switches of the second plurality of switches are open, or a fourth state in which each of the second plurality of switches are open; and configuring a termination switch (if provided), coupled between the second common output node and a termination (if provided) to either: a fifth state in which the termination switch is closed, or a sixth state in which the termination switch is open.

In another example, an apparatus is described. The apparatus includes means for configuring a first plurality of switches coupled between respective ones of a first plurality of input nodes and a first common output node to either: a first state in which a first switch of the first plurality of switches is closed and remaining switches of the first plurality of switches are open, or a second state in which each of the first plurality of switches are open. The apparatus further includes means for configuring a second plurality of switches coupled between respective ones of a second plurality of input nodes and a second common output node to either: a third state in which a second switch of the second plurality of switches is closed and remaining switches of the second plurality of switches are open, or a fourth state in which each of the second plurality of switches are open. The apparatus still further includes means for configuring a termination switch (if provided), coupled between the second common output node and a termination (if provided) to either a fifth state in which the termination switch is closed, or a sixth state in which the termination switch is open. To the accomplishment of the foregoing and related ends, the one or more implementations include the features hereinafter fully described and particularly pointed out in the claims. The following description and the appended drawings set forth in detail certain illustrative aspects of the one or more implementations. These aspects are indicative, however, of but a few of the various ways in which the principles of various implementations may be employed, and the description implementations are intended to include all such aspects and their equivalents. The relative dimensions of the following figures may not be drawn to scale.

### BRIEF DESCRIPTION OF THE DRAWINGS

FIG. 1 is a schematic illustration of an example wireless communication system according to some aspects of the disclosure.

FIG. 2 is a simplified block diagram of a transceiver according to some aspects of the disclosure.

FIG. 3 is a graphic representation of each frequency band listed in Table 1.

FIG. 4 is a simplified schematic drawing of a radio frequency (RF) front-end (RFFE) module according to some aspects of the disclosure.

FIG. 5 is a simplified schematic drawing of a plurality of bandpass filters, an M:1 switch matrix, a matching network, and a low noise amplifier according to some aspects of the disclosure.

FIGS. 6A and 6B are plots of S11 and noise figure, respectively, for the series-only inductor of the matching network as shown and described in connection with FIG. 5.

FIG. 7 is a simplified schematic drawing of a plurality of bandpass filters, an M:1 switch matrix, a matching network, and a low noise amplifier according to some aspects of the disclosure.

FIGS. 8A and 8B are plots of S11 and noise figure, respectively, for a shunt-series pair of inductors of the matching network as shown and described in connection with FIG. 7.

FIG. 9 is a simplified schematic drawing of a plurality of bandpass filters, an M:1 switch matrix, a matching network, and a low noise amplifier according to some aspects of the disclosure.

FIGS. 10A, 10B, and 10C are graphs of S11, noise figure, and S21 for the matching network as shown and described in connection with FIG. 9.

FIG. 11 is a simplified schematic drawing of a plurality of bandpass filters, a first switch matrix, a second switch matrix, a first series-only inductor, a second series-only inductor, a first low noise amplifier, and a second low noise amplifier according to some aspects of the disclosure.

FIG. 12 is a simplified schematic drawing of a plurality of bandpass filters, a switch matrix, a first series inductor in series with a second series inductor, a bypass circuit to short circuit the first series inductor, and a low noise amplifier, according to some aspects of the disclosure.

FIG. 13 is a simplified schematic drawing of an RFFE module according to some aspects of the disclosure.

FIG. 14 is a simplified schematic drawing of a portion of FIG. 13 according to some aspects of the disclosure.

FIGS. 15A and 15B are first alternative and second alternative simplified schematic drawings of FIG. 14, according to some aspects of the disclosure.

FIGS. 16A, 16B, and 16C show three instantiations of the apparatus of FIG. 14 according to some aspects of the disclosure.

FIGS. 17A, 17B, and 17C are graphs of S11, noise figure, and S21 according to some aspects of the disclosure.

FIG. 18 is a Smith chart depicting the impedance looking into an output of a given configuration of a matching network as the frequency is swept from 610 MHz to 660 MHz, according to some aspects of the disclosure.

FIG. 19 is a Smith chart depicting the impedance looking into an output of a given configuration of a matching network as the frequency is swept from 900 MHz to 960 MHz, according to some aspects of the disclosure.

FIGS. 20A and 20B are graphs of voltage standing wave ratio (VSWR) and noise figure simulations utilizing an n71 filter over a swept frequency ranging from 600 MHz to 670 MHz according to some aspects of the disclosure.

FIGS. 21A, 21B, and 21C are simplified schematic drawings of three instantiations of a configurable low noise amplifier input matching network according to some aspects of the disclosure.

FIG. 22 is a block diagram illustrating an example of a hardware implementation of an apparatus employing one or more processing systems according to some aspects of the disclosure.

FIG. 23 is a flow chart illustrating an example process at an apparatus according to some aspects of the disclosure.

FIG. 24 is a flow chart illustrating an example process at an apparatus according to some aspects of the disclosure.

Like reference numbers and designations in the various drawings indicate like elements.

### DETAILED DESCRIPTION

The detailed description set forth below in connection with the appended drawings is directed to some particular examples for the purpose of describing innovative aspects of this disclosure. However, a person having ordinary skill in the art will readily recognize that the teachings herein can be applied in a multitude of different ways. Some or all of the described examples may be implemented in any device, system, or network that is capable of transmitting and receiving radio frequency (RF) signals according to one or more of the Institute of Electrical and Electronics Engineers (IEEE) 802.11 (WiFi®) standards, the IEEE 802.15 standards, the Bluetooth® standards as defined by the Bluetooth Special Interest Group (SIG), or the Long Term Evolution (LTE), 3G, 4G or 5G (New Radio (NR)) standards promulgated by the 3rd Generation Partnership Project (3GPP), among others. The described examples can be implemented in any device, system, or network that is capable of transmitting and receiving RF signals according to one or more of the following technologies or techniques: code division multiple access (CDMA), time division multiple access (TDMA), frequency division multiple access (FDMA), orthogonal FDMA (OFDMA), single-carrier FDMA (SC-FDMA), spatial division multiple access (SDMA), rate-splitting multiple access (RSMA), multi-user shared access (MUSA), single-user (SU) multiple-input multiple-output (MIMO) and multi-user (MU)-MIMO. The described examples also can be implemented using other wireless communication protocols or RF signals suitable for use in one or more of a wireless personal area network (WPAN), a wireless local area network (WLAN), a wireless wide area network (WWAN), a wireless metropolitan area network (WMAN), or an internet of things (IoT) network.

The detailed description set forth below, in connection with the appended drawings, is intended as a description of various configurations and is not intended to represent the only configurations in which the concepts described herein may be practiced. The detailed description includes specific details to provide a thorough understanding of the various concepts. However, it will be apparent to persons having ordinary skill in the art that these concepts may be practiced without these specific details. In some instances, well-known structures and components are shown in block diagram form in order to avoid obscuring such concepts.

While aspects and examples are described in this application by illustration to some examples, persons having ordinary skill in the art will understand that additional implementations and use cases may come about in many different arrangements and scenarios. Innovations described herein may be implemented across many differing platform types, devices, systems, shapes, sizes, and packaging arrangements. For example, aspects and/or uses may come about via integrated chip examples and other non-module-component-based devices (e.g., end-user devices, vehicles, communication devices, computing devices, industrial equipment, retail/purchasing devices, medical devices, artificial intelligence (AI)-enabled devices, etc.). While some examples may or may not be specifically directed to use cases or applications, a wide assortment of applicability of described innovations may occur. Implementations may range a spectrum from chip-level or modular components to non-modular, non-chip-level implementations and further to aggregate, distributed, or original equipment manufacturer (OEM) devices or systems incorporating one or more aspects of the described innovations. In some practical settings, devices incorporating described aspects and features may also necessarily include additional components and features for implementation and practice of claimed and described examples. For example, transmission and reception of wireless signals necessarily includes a number of components for analog and digital purposes (e.g., hardware components including antenna, RF-chains, power amplifiers, modulators, buffer, processor(s), interleaver, adders/summers, etc.). It is intended that innovations described herein may be practiced in a wide variety of devices, chip-level components, systems, distributed arrangements, disaggregated arrangements (e.g., base station and/or user equipment (UE)), end-user devices, etc. of varying sizes, shapes, and constitution.

Described herein are hardware and methods to configurably match an input impedance of a low noise amplifier to an output impedance of a preselector. The preselector, which may include a plurality of bandpass filters corresponding to a plurality of channel center frequencies and bandwidths that the preselector may receive, may not present a constant impedance at its output for all the channels. The differing output impedances may result from the corresponding differing output impedances of each bandpass filter used in the preselector. Although bandpass filters are described herein, other types of filters may be within the scope of the disclosure.

The plurality of bandpass filters may each be tuned to a respective channel center frequency and bandwidth. Each bandpass filter may be configured to prevent or reduce signals outside of the bandwidth of the bandpass filter (e.g., outside the bandwidth of the channel that corresponds to the bandpass filter) from being input to the low noise amplifier coupled to the output of the preselector. For example, and without any intent of limiting the specification, if a desired channel was the 3GPP 5G NR channel n71, the preselector may be configured to pass all signals received at the antenna through the bandpass filter tuned to channel n71. The signals from other channels, above and below channel n71, would be attenuated by the bandpass filter tuned to channel n71. Accordingly, the RF preselector may be used to prevent or reduce the amplitude of out-of-band signals (e.g., in this example, signals above and below those signals in channel n71) at the input of the low noise amplifier.

The preselector may selectively multiplex the signal received at an antenna of a communication device to one of a plurality of bandpass filters included in the preselector. The preselector may then selectively demultiplex the signal passed through the one of the plurality of bandpass filters to an output of the preselector's demultiplexer(s). Thus, the preselector may be thought of as a tunable bandpass filter. However, as mentioned, the impedance, looking back into the output of the preselector, changes depending on the bandpass filter selected. Accordingly, a low noise amplifier input matching network may be configured between the output of the preselector's demultiplexer(s) and the input of the low noise amplifier. The low noise amplifier input matching network may match the various output impedances of the plurality of bandpass filters included in the preselector to the input impedance of the low noise amplifier.

A preselector having a plurality of bandpass filters may be included in a radio frequency (RF) front-end (RFFE) module. The RFFE module may provide a selectable path between an RFFE module input and an RFFE module output via a respective one of the plurality of bandpass filters and the low noise amplifier. Because the RFFE module, and its included preselector, may cover numerous cellular and connectivity bands, the low noise amplifier of the RFFE module may also cover the same cellular and connectivity bands. The input impedance of the low noise amplifier may vary over the bandwidth of the low noise amplifier. The input and output impedances of each of the plurality of bandpass filters is generally understood to be relatively constant within the bandwidth of a given bandpass filter. The input impedance of the low noise amplifier in a given bandwidth of a respective bandpass filter, transformed back from the input of the low noise amplifier through a matching network and at least one switch (e.g., the switch of the demultiplexer associated with the respective bandpass filter) may be different relative to the center frequency and bandwidth of the bandpass filter under consideration.

Accordingly, one set of lumped elements and/or distributed elements that together form a matching network may be inadequate to provide maximum available gain and lowest noise figure in each of the plurality of bandwidths the preselector serves. In other words, given the plurality of low noise amplifier input impedances associated with the respective plurality of center frequencies and bandwidths of the plurality of bandpass filters, a fixed matching network that covers the entire bandwidth served by the RFFE module may be inadequate. Various methods and structures implementing multiple matching networks over multiple frequency bands have been tried but have been unsuccessful. Described herein are structures and methods that may provide a configurable low noise amplifier impedance matching network that may be implemented in RFFEs according to some aspects of the disclosure. The various concepts presented throughout this disclosure may be implemented across a broad variety of telecommunication systems, network architectures, and communication standards.

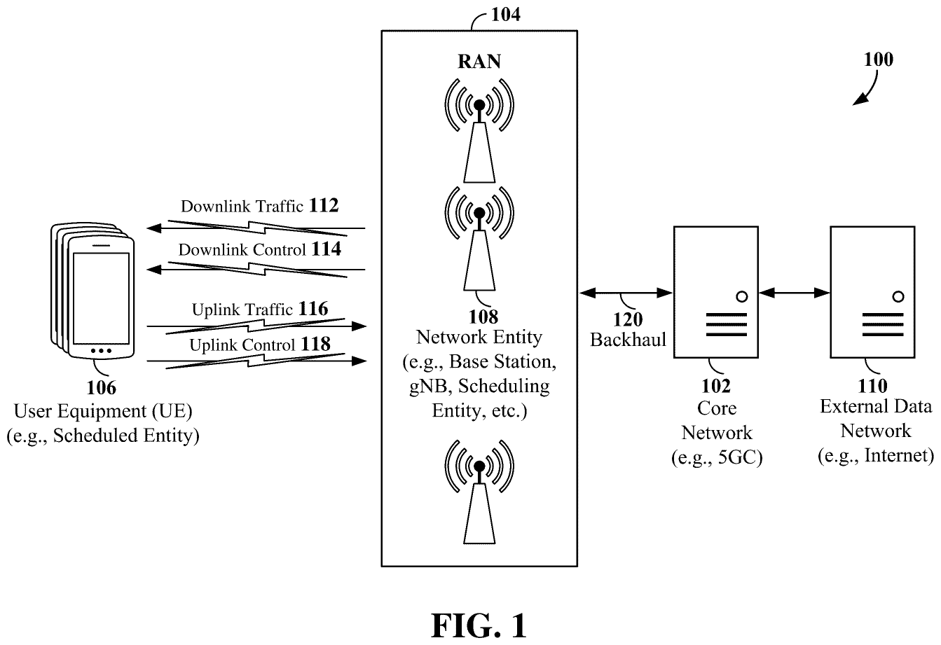

FIG. 1 is a schematic illustration of an example of a wireless communication system 100 according to some aspects of the disclosure. The wireless communication system 100 includes three interacting domains: a core network 102, a radio access network (RAN) 104, and a user equipment (UE) 106. By virtue of the wireless communication system 100, the UE 106 (also referred to herein as a wireless communication device) may be enabled to carry out data communication with an external data network 110, such as (but not limited to) the Internet. The UE 106 may include a transceiver having an RFFE module (not shown to avoid cluttering the drawing) such as those described herein in accordance with various aspects of the disclosure.

The RAN 104 may implement any suitable wireless communication technology or technologies to provide radio access to the UE 106. The UE may include a transceiver having an RFFE module such as those described herein in accordance with various aspects of the disclosure. As one example, the RAN 104 may operate according to the European telecommunications standards institute (ETSI) global system for mobile communications (GSM) specifications. As another example, the RAN 104 may operate according to 3rd Generation Partnership Project (3GPP) New Radio (NR) specifications, often referred to as 5G. As a further example, the RAN 104 may operate under a hybrid of 5G NR and Evolved Universal Terrestrial Radio Access Network (eUTRAN) standards, often referred to as Long-Term Evolution (LTE). The 3GPP refers to this hybrid RAN as a next-generation RAN, or NG-RAN. In another example, the RAN 104 may operate according to both the LTE and 5G NR standards. Of course, many other examples may be utilized within the scope of the present disclosure.

As illustrated, the RAN 104 includes a plurality of network entities 108. Broadly, a network entity may be implemented in an aggregated or monolithic base station architecture, or in a disaggregated base station architecture, and may include one or more of a central unit (CU), a distributed unit (DU), a radio unit (RU), a Near-Real Time (Near-RT) RAN Intelligent Controller (RIC), or a Non-Real Time (Non-RT) RIC. In some examples, a network entity may be a network element in a radio access network responsible for radio transmission and reception in one or more cells to or from a UE. In different technologies, standards, or contexts, a network entity may variously be referred to by persons having ordinary skill in the art as a base transceiver station (BTS), a radio base station, a base station, a radio transceiver, a transceiver function, a basic service set (BSS), an extended service set (ESS), an access point (AP), a Node B (NB), an eNode B (eNB), a gNode B (gNB), a transmission and reception point (TRP), a scheduling entity, a network entity, or some other suitable terminology. In some examples, a network entity may include two or more TRPs that may be collocated or non-collocated. Each TRP may communicate on the same or different carrier frequency within the same or different frequency band. In examples where the RAN 104 operates according to both the LTE and 5G NR standards, one of the network entities may be an LTE network entity, while another network entity may be a 5G NR network entity.

The RAN 104 is further illustrated supporting wireless communication for multiple mobile apparatuses. A mobile apparatus may be referred to as user equipment (UE) in 3GPP standards, but may also be referred to by persons having ordinary skill in the art as a mobile station (MS), a subscriber station, a mobile unit, a subscriber unit, a wireless unit, a remote unit, a mobile device, a wireless device, a wireless communication device, a remote device, a mobile subscriber station, an access terminal (AT), a mobile terminal, a wireless terminal, a remote terminal, a handset, a terminal, a user agent, a mobile client, a client, a scheduled entity, or some other suitable terminology. A UE 106 may be an apparatus (e.g., a scheduled entity, a user equipment, a wireless communications device, a mobile communication device) that provides a user with access to network services.

The terms UE, scheduled entity, mobile apparatus, and mobile device broadly refer to a diverse array of devices and technologies. Within the present disclosure, a “mobile” apparatus need not necessarily have a capability to move and may be stationary. UEs may include a number of hardware structural components sized, shaped, and arranged to help in communication; such components can include antennas, antenna arrays, RF front-ends, RF chains, amplifiers, one or more processors, etc., electrically coupled to each other. For example, some non-limiting examples of a mobile apparatus include a mobile, a cellular (cell) phone, a smart phone, a session initiation protocol (SIP) phone, a laptop, a personal computer (PC), a notebook, a netbook, a smartbook, a tablet, a personal digital assistant (PDA), and a broad array of embedded systems, e.g., corresponding to an Internet of Things (IoT).

A UE may additionally be incorporated into or include an automotive or other transportation vehicle, a remote sensor or actuator, a robot or robotics device, a satellite radio, a global positioning system (GPS) device, an object tracking device, a drone, a multi-copter, a quad-copter, a remote control device, a consumer and/or wearable device, such as eyewear, a wearable camera, a virtual reality device, a smart watch, a health or fitness tracker, a digital audio player (e.g., MP3 player), a camera, a game console, etc. A UE may additionally be a digital home or smart home device such as a home audio, video, and/or multimedia device, an appliance, a vending machine, intelligent lighting, a home security system, a smart meter, etc. A UE may additionally be a smart energy device, a security device, a solar panel or solar array, a municipal infrastructure device controlling electric power (e.g., a smart grid), lighting, water, etc., an industrial automation and enterprise device, a logistics controller, agricultural equipment, etc. Still further, a UE may provide for connected medicine or telemedicine support, i.e., health care at a distance. Telehealth devices may include telehealth monitoring devices and telehealth administration devices, whose communication may be given preferential treatment or prioritized access over other types of information, e.g., in terms of prioritized access for transport of critical service data, and/or relevant QoS for transport of critical service data.

Wireless communication between the RAN 104 and the UE 106 may be described as utilizing an air interface. Transmissions over the air interface from a base station (e.g., base station 108) to one or more UEs (e.g., similar to UE 106) may be referred to as downlink (DL) transmission. In accordance with certain aspects of the present disclosure, the term downlink may refer to a point-to-multipoint transmission originating at a base station (e.g., base station 108). Another way to describe this point-to-multipoint transmission or a point-to-point transmission (e.g., groupcast, multicast, or unicast) originating at a network entity (e.g., similar to network entity 108). Another way to describe this scheme may be to use the term broadcast channel multiplexing. Transmissions from a UE (e.g., UE 106) to a network entity (e.g., network entity 108) may be referred to as uplink (UL) transmissions. In accordance with further aspects of the present disclosure, the term uplink may refer to a point-to-point transmission originating at a UE (e.g., UE 106).

In some examples, access to the air interface may be scheduled, where a network entity (e.g., similar to network entity 108) allocates resources for communication among some or all devices and equipment within its service area or cell. Within the present disclosure, as discussed further below, the network entity may be responsible for scheduling, assigning, reconfiguring, and releasing resources for one or more scheduled entities (e.g., UEs 106). That is, for scheduled communication, a plurality of UEs 106, which may be scheduled entities, may utilize resources allocated by the network entity 108.

Network entities 108 are not the only entities that may function as scheduling entities. That is, in some examples, a UE may function as a scheduling entity, scheduling resources for one or more scheduled entities (e.g., one or more other UEs). For example, UEs may communicate with other UEs in a peer-to-peer or device-to-device fashion and/or in a relay configuration.

As illustrated in FIG. 1, the network entity 108 may broadcast downlink traffic 112 (also referred to as downlink data traffic) to one or more UEs 106. Broadly, the network entity 108 may be a node or device responsible for scheduling traffic (e.g., data traffic, user data traffic) and scheduling control (e.g., control information) in a wireless communication network, including the downlink traffic 112 and/or downlink control 114 and, in some examples, uplink traffic 116 and/or uplink control 118 from one or more scheduled entities to the scheduling entity. On the other hand, the UE 106 (e.g., the scheduled entity) may be a node or device that receives downlink traffic 112 and downlink control 114, including but not limited to scheduling information (e.g., a grant), synchronization or timing information, or other control information from another entity in the wireless communication network such as the network entity 108. The UE 106 may further transmit uplink control 118 information, including but not limited to a scheduling request or feedback information, or other control information to the network entity 108.

The uplink control 118 information, downlink control 114 information, downlink traffic 112, and/or uplink traffic 116 may transmitted on a waveform that may be time-divided into frames, subframes, slots, and/or symbols. As used herein, a symbol may refer to a unit of time that, in an orthogonal frequency division multiplexed (OFDM) waveform, carries one resource element (RE) per sub-carrier. A slot may carry a certain number of OFDM symbols (e.g., 7 or 14 OFDM symbols) in some examples. A subframe may refer to a specified duration (e.g., 1 millisecond (ms)). Multiple subframes or slots may be grouped together to form a single frame or radio frame. Within the present disclosure, a frame may refer to a predetermined duration (e.g., 10 ms) for wireless transmissions, with each frame consisting of, for example, 10 subframes of 1 ms each. Of course, these definitions are not required, and any suitable scheme for organizing waveforms may be utilized, and various time divisions of the waveform may have any suitable duration.

In general, each network entity 108 may include a backhaul interface (not shown) for communication with a backhaul portion 120 of the wireless communication system. The backhaul portion 120 may provide a link between a network entity 108 and the core network 102. Further, in some examples, a backhaul network may provide interconnection between respective network entities 108. Various types of backhaul interfaces may be employed, such as a direct physical connection, a virtual network, or the like using any suitable transport network.

The core network 102 may be a part of the wireless communication system 100 and may be independent of the radio access technology used in the RAN 104. In some examples, the core network 102 may be configured according to ETSI standards, 5G standards (e.g., 5G core (5GC)), or according to other 3GPP standards such as a 4G evolved packet core (EPC) or any other suitable standard or configuration.

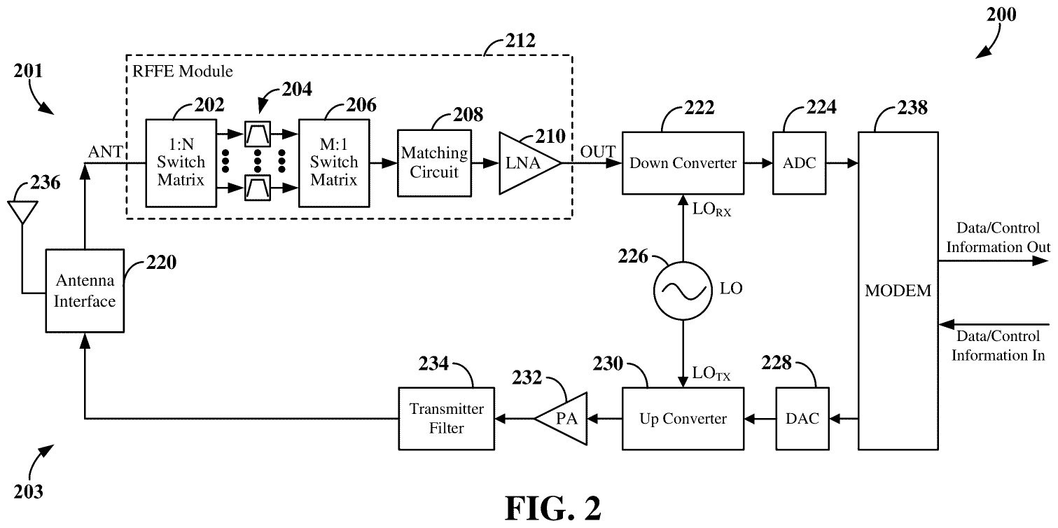

FIG. 2 is a simplified block diagram of a transceiver 200 according to some aspects of the disclosure. The transceiver 200 includes a receiver side 201 and a transmitter side 203. An antenna 236 is coupled to an antenna interface 220. The antenna 236 may be an antenna array. The antenna interface 220 directs signals received at the antenna 236 to a 1: N switch matrix 202 (e.g., a multiplexer) of the receiver side 201. Here, N is a non-zero positive integer. The antenna interface 220 also receives signals to be transmitted from the antenna 236, to be described further below.

Returning to the receiver side 201, the transceiver 200 includes a plurality of bandpass filters 204 (e.g., surface acoustic wave (SAW) filters, bulk acoustic wave (BAW) filters, film bulk acoustic resonator (FBAR) filters, or other types of filters are within the scope of the disclosure). Each filter of the plurality of bandpass filters 204 may be tuned to a respective center frequency of the frequency band reserved for wireless communications. The bandwidth of each filter may depend on the frequency band handled by that filter and the channel bandwidth associated with the frequency band. For example, frequency bands for 5G New Radio (5G NR) are separated into two frequency ranges: Frequency Range 1 (FR1) and Frequency Range 2 (FR2). FR1 includes sub-6 GHz frequency bands but has been extended to cover potential new spectrum offerings from 410 MHz to 7125 MHz. FR2 includes frequency bands from 24.25 GHz to 71.0 GHz.

Respective ones of the plurality of bandpass filters 204 may be coupled to an M:1 switch matrix 206 (e.g., a demultiplexer) of the receiver side 201. Here, M is a non-zero positive integer. M may be equal to, less than, or greater than N (e.g., the 1:N switch matrix 202 may include an extra switch(es) that are coupled to other devices, loads, or may be spare switches, and the M:1 switch matrix 206 may include an extra switch(es) that is coupled to other devices, loads, or may be spare switches). In some examples, the 1:N switch matrix 202 and the M:1 switch matrix 206 may be referred to individually or collectively as preselector switches. The 1:N switch matrix 202 and the M:1 switch matrix 206 may be controlled by a processor of a processing system via a radio frequency (RF) front-end (RFFE) control interface (not shown). The RFFE control interface may be included with the transceiver 200. For example, the RFFE control interface may be included in an integrated circuit carrying the 1:N switch matrix 202, the M:1 switch matrix 206, and the low noise amplifier 210, or may be included in an RF front-end (RFFE) module 212 including the 1:N switch matrix 202, plurality of bandpass filters 204, the M:1 switch matrix 206, the matching network 208, and the low noise amplifier 210. These locations are exemplary and non-limiting.

The M:1 switch matrix 206 may be coupled to a matching network 208. The matching network 208 may be coupled to the low noise amplifier 210. The matching network 208 may match the output impedance of the M:1 switch matrix 206 to the input impedance of the low noise amplifier 210. In some examples, the low noise amplifier 210 may have a 50 Ohm input impedance. Other impedances are within the scope of the disclosure.

Continuing on the receiver side 201, the transceiver 200 may also include one or more frequency down-converter (DC) stages (represented by down-converter 222) and an analog-to-digital converter (ADC) 224. The down-converter 222 receives a local oscillator (LO) signal (LO_{RX}) from an LO 226.

Turning to the transmitter side 203, the transceiver includes a digital-to-analog converter (DAC) 228, one or more frequency up-converter stages (represented by up-converter 230), a power amplifier (PA) 232, and a transmitter filter 234. The up-converter 230 receives a local oscillator (LO) signal (LO_{TX}) from the LO 226. According to some aspects, the transmitter filter 234 may be a second plurality of transmitter filters (not shown) (e.g., surface acoustic wave (SAW) filters, bulk acoustic wave (BAW) filters, film bulk acoustic resonator (FBAR) filters, or other types of filters are within the scope of the disclosure). The transmitted signal may be routed through respective ones of the second plurality of transmitter filters via a switch network similar to that shown for the receiver side 201 (e.g., similar to the 1:N switch matrix 202 and the M:1 switch matrix 206).

The transceiver 200 additionally includes a modem 238. For a transceiver that is a part of a UE (e.g., a scheduled entity similar to the UE 106 as shown and described in FIG. 1), the modem 238 receives user data and control signaling from a processor of a processing system, modulates the user data and control signaling, and presents the modulated information to the DAC 228. The DAC 228 converts the digital information received from the modem 238 and presents the baseband analog information to the up-converter 230. The up-converter 230 mixes the baseband analog information with the signal from the LO 226 to up-convert the baseband analog information to a transmission frequency in an uplink band (e.g., in the uplink frequencies of band n8, n13, n14, n20, n26, or n71) for transmission to a network entity or other scheduled entity (e.g., similar to the network entity 108 as shown and described in connection with FIG. 1). The up-converted signal is applied to the PA 232, which amplifies the signal for transmission. The amplified signal is passed through the transmitter filter 234 and the antenna interface 220 for transmission from the antenna 236 according to some aspects of the disclosure.

Again, for a transceiver that is a part of the UE, a downlink signal at a frequency in a downlink band (e.g., in the downlink frequencies of band n8, n13, n14, n20, n26, n29, or n71) is received by the antenna 236 and passed from the antenna 236 to the RFFE module 212, where it is filtered, impedance matched, and amplified (by the 1:N switch matrix 202, the plurality of bandpass filters 204, the M:1 switch matrix 206, the matching network 208, and the low noise amplifier 210). The amplified signal is presented to the down-converter 222, which mixes the analog information at the transmission frequency (e.g., downlink bands of n8, n13, n14, n20, n26, n29, or n71) to baseband analog information with the signal from the LO 226. The ADC 224 receives the baseband signal from the down-converter 222 and converts it to digital information that is applied to the modem 238. The modem 238 demodulates the information and passes it to the processor of the processing system.

Conversely, for a transceiver that is a part of a network entity (e.g., similar to the network entity UE 108 as shown and described in FIG. 1), the modem 238 receives user data and control signaling from a processor of a processing system, modulates the user data and control signaling, and presents the modulated information to the DAC 228. The DAC 228 converts the digital information received from the modem 238 and presents the baseband analog information to the up-converter 230. The up-converter 230 mixes the baseband analog information with the signal from the LO 226 to up convert the baseband analog information to a transmission frequency in a downlink band (e.g., in the downlink link frequencies of band n8, n13, n14, n20, n26, n29, or n71) for transmission to a UE (e.g., similar to the UE 106 as shown and described in connection with FIG. 1). The up converted signal is applied to the PA 232, which amplifies the signal for transmission. The amplified signal is passed through the transmitter filter 234 and the antenna interface 220 for transmission from the antenna 236 according to some aspects of the disclosure.

Again, for a transceiver that is a part of the network entity, an uplinked signal at a frequency in an uplink band (e.g., in the uplink frequencies of band n8, n13, n14, n20, n26, or n71) is received by the antenna 236 and passed from the antenna 236 to the RFFE module 212, where it is filtered, impedance matched, and amplified (by the 1:N switch matrix 202, the plurality of bandpass filters 204, the M:1 switch matrix 206, the matching network 208, and the low noise amplifier 210). The amplified signal is presented to the down-converter 222, which mixes the analog information at the transmission frequency (e.g., uplink bands of n8, n13, n14, n20, n26, or n71) to baseband analog information with the signal from the LO 226. The ADC 224 receives the baseband signal from the down-converter 222 and converts it to digital information that is applied to the modem 238. The modem 238 demodulates the information and passes it to the processor of the processing system.

Table 1 provides some information regarding each of the 5G NR bands exemplified herein (i.e., 5G NR bands n8, n20, n26, n13, and n14 (which share one filter), n29, and n71). Although Table 1 only shows duplex modes of frequency division duplexing (FDD) and SDL in FR1, other duplex modes, such as time division duplexing (TDD) and FDD supplemental uplink (SUL) in different operating bands (not limited to 5G NR) are within the scope of the disclosure. The examples in Table 1 are meant to be illustrative and non-limiting.

TABLE 1

| | Duplex | | Uplink | Downlink | Channel bandwidth |
|---|---|---|---|---|---|
| Band | Mode | Name | (MHz) | (MHz) | (MHz) |
| n8 | FDD | 900 | 880-915 | 925-960 | 5, 10, 15, 20, 25¹, 35¹ |
| n13 | FDD | 700 c | 777-787 | 746-756 | 5, 10 |
| n14 | FDD | 700 PS | 788-798 | 758-768 | 5, 10 |
| n20 | FDD | 800 | 832-862 | 791-821 | 5, 10, 15, 20 |
| n26 | FDD | 850+ | 814-849 | 859-894 | 5, 10, 15, 20, 25², 30² |
| n29 | SDL³ | 700 d | — | 717-728 | 5, 10 |
| n71 | FDD | 600 | 663-698 | 617-652 | 5, 10, 15, 20, 25¹, 30¹, |
| | | | | | 35¹ |

¹Downlink only
²Carrier aggregation and downlink only
³FDD supplemental downlink (SDL)

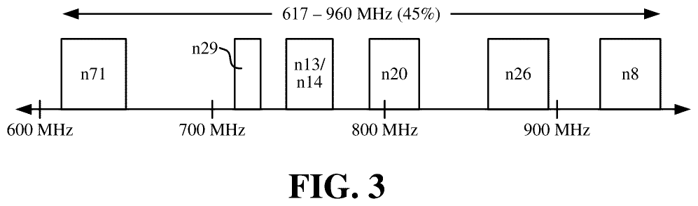

FIG. 3 is a graphic representation of each frequency band listed in Table 1, where frequency is represented on the horizontal axis in units of MHz. As depicted in FIG. 3, the plurality of bands listed in Table 1 spans from 617 MHz to 960 MHz (343 MHz total), corresponding to a 45 percent bandwidth.

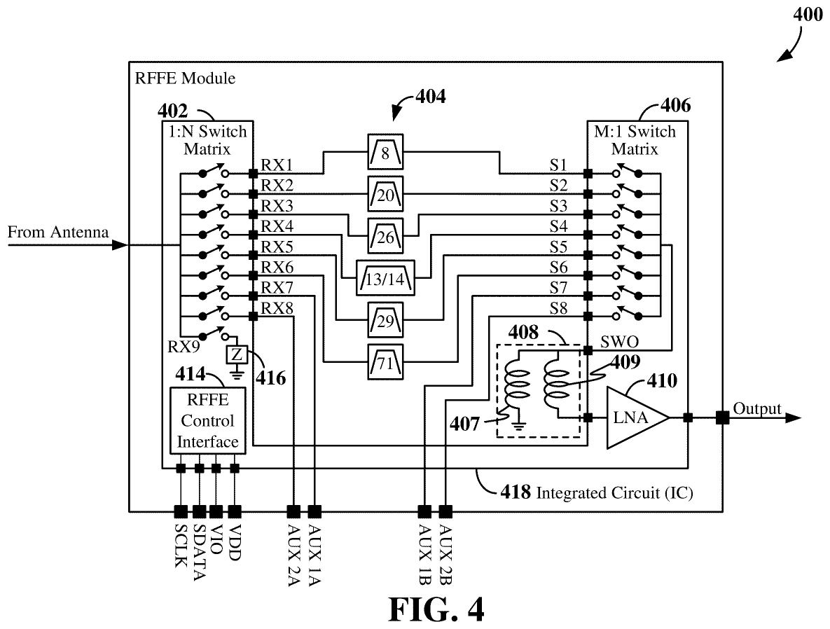

FIG. 4 is a simplified schematic drawing of a radio frequency (RF) front-end (RFFE) module 400 according to some aspects of the disclosure. The RFFE module 400 may be similar to the RFFE module 212, as shown and described in connection with FIG. 2. For example, the RFFE module 400 may include a plurality of bandpass filters 404 (similar to the plurality of bandpass filters 204 as shown and described in connection with FIG. 2). In the example of FIG. 4 and the remaining examples in this disclosure, filters associated with 5G NR bands n8, n20, n26, n13, and n14 (which share one filter), n29, and n71 will be used for exemplary and non-limiting purposes.

The RFFE module 400 may include a 1:N switch matrix 402 (similar to the 1: N switch matrix 202 as shown and described in connection with FIG. 2). In the example of FIG. 4, the 1:N switch matrix 402 includes nine single-pole single-throw (SPST) switches labeled RX1 through RX9 (i.e., N-9). SPST RX1-RX6 are coupled to respective filters. SPST RX7 is coupled to a port (also referred to as an auxiliary (AUX) port or a bump herein) labeled AUX 1A. SPST RX8 is coupled to a port labeled AUX 2A. In a closed state (not shown), SPST RX9 is coupled to a grounded load Z 416. The value of the load Z 416 may be 50 Ohms in some examples. The load Z 416 may be used for testing or in situations where it is desirable to present a known load (e.g., 50 Ohms to ground) at the input (i.e., where the input is labeled “From Antenna”) of the RFFE module 400, as opposed to presenting an open circuit at the input of the RFFE module 400.

The RFFE module 400 may include an M:1 switch matrix 406 (similar to the M:1 switch matrix 206 as shown and described in connection with FIG. 2). In the example of FIG. 4, the M:1 switch matrix 406 includes eight single-pole single-throw (SPST) switches labeled S1 through S8 (i.e., M=8). SPST S1-S6 are coupled to respective filters. SPST S7 is coupled to a port (also referred to as a bump herein) labeled AUX 1B. SPST S8 is coupled to a port (also referred to as a bump herein) labeled AUX 2B. A device (e.g., a filter) or test equipment may be placed between AUX 1A and AUX 1B for test purposes or other reasons. If so placed, a circuit from the input of the RFFE module 400 (labeled “From Antenna”) to the port labeled SWO of the M:1 switch matrix 406, including the device or test equipment in series between AUX 1A and AUX 1B, would be made in response to closing the SPST switch RX7 and the SPST switch S7. Similarly, a device (e.g., a filter) or test equipment may be placed between AUX 2A and AUX 2B for test purposes or any other reason. If so placed, a circuit from the input of the RFFE module 400 (labeled “From Antenna”) to the port labeled SWO of the M:1 switch matrix 406, including the device or test equipment in series between AUX 2A and AUX 2B, would be made in response to closing the SPST switch RX8 and the SPST switch S8.

The 1:N switch matrix 402 and the M:1 switch matrix 406 are relatively wideband relative to the overall bandwidth of the RFFE module 400. On the other hand, each of the plurality of bandpass filters 404 is relatively narrowband relative to the overall bandwidth of the RFFE module 400. For example, as illustrated in FIG. 3, the overall bandwidth of the RFFE module 400 is 343 MHz, while the downlink bandwidth of the n71 band is 35 MHz. The downlink bandwidths of the n29, n13/n14, n20, n26, and n8 bands are 11 MHz, 10 MHz, 30 MHz, 35 MHz, and 35 MHz, respectively. The impedance looking into the low noise amplifier 410 varies with frequency over the entire 343 MHz bandwidth of the RFFE module 400. The matching network 408 is represented in the example of FIG. 4 as a fixed series inductor 409 and fixed shunt inductor 407. In other examples, a fixed series inductor may be used. These fixed lumped elements may not provide adequate matching between the output of the M:1 switch matrix 406 and the low noise amplifier 410 over the entire bandwidth of the low noise amplifier 410.

The RFFE module 400 includes an RFFE control interface 414. In one example, the RFFE control interface may comply with specifications promulgated by the Mobile Industry Processor Interface (MIPI®) Alliance. Other specifications for the RFFE control interface are within the scope of the disclosure. A processor of a processing system may drive the RFFE control interface 414 via the port labeled SDATA. The RFFE control interface 414 may receive a system clock signal via the SCLK port. Voltage may be applied to the ports labeled VDD and VIO. The RFFE control interface 414 may drive the opening and closing of the SPST switches in the 1:N switch matrix 402 and the M:1 switch matrix 406. Connections between the RFFE control interface 414 and the plurality of SPST switches of the 1:N switch matrix 402 and the M:1 switch matrix 406 are omitted to avoid cluttering the drawing.

In some examples, the 1:N switch matrix 402, the M:1 switch matrix 406, the low noise amplifier 410, the RFFE control interface 414, and the grounded load Z 416 may all be included in an integrated circuit (IC) 418 (represented with a block-U-shaped outline) including the 1:N switch matrix 402, the M:1 switch matrix 406, the low noise amplifier 410, and the RFFE control interface 414, and the grounded load Z 416 within its boundaries. Of course, including these components in an IC, such as IC 418, is exemplary and non-limiting. Other organizations and formats (e.g., thin film, thick film, combinations of discrete and integrated circuits) and the inclusion of some or all of these components are within the scope of the disclosure.

The RFFE module 400 may also include a matching network 408 (similar to the matching network 208 as shown and described in connection with FIG. 2) between the output of the M:1 switch matrix 406 (at a port, or bump, identified as “SWO”) and the input of the low noise amplifier 410. In the non-limiting example of FIG. 4, the matching network 408 has the form of a shunt-series matching network that includes two inductors: a shunt inductor 407 and a series inductor 409, all as shown in FIG. 4. As used herein, the convention when identifying a type of matching network will first refer to the component closest to the antenna, and proceed forward toward the low noise amplifier. Accordingly, the matching network 408 is referred to as a shunt-series matching network.

It is noted that the RFFE module 400 may include other elements (e.g., matching elements for the filters, electrostatic discharge protection, supply voltage filtering, etc.) that are not shown to avoid cluttering the drawing.

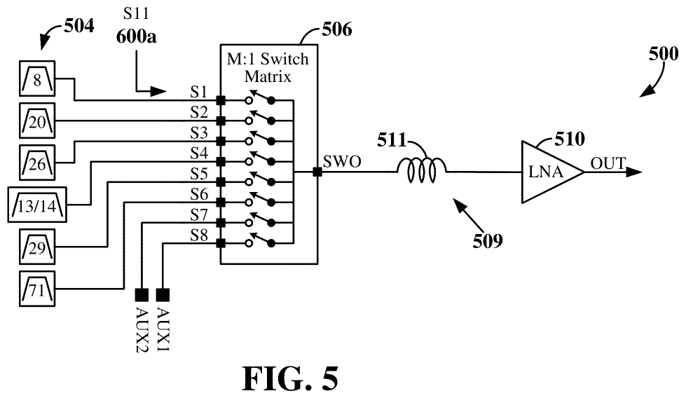

FIG. 5 is a simplified schematic drawing of a plurality of bandpass filters 504, an M:1 switch matrix 506, a matching network 509, and a low noise amplifier 510 according to some aspects of the disclosure. The plurality of bandpass filters 504 may be similar to the plurality of bandpass filters 204, 404 as shown and described in connection with FIGS. 2 and 4, respectively. The M:1 switch matrix 506 may be similar to the M:1 switch matrix 206, 406 as shown and described in connection with FIGS. 2 and 4, respectively. The low noise amplifier 510 may be similar to the low noise amplifier 210, 410 as shown and described in connection with FIGS. 2 and 4, respectively. Detailed descriptions of the plurality of bandpass filters 504, the M:1 switch matrix 506, and the low noise amplifier 510 are omitted to avoid duplication and for the sake of brevity.

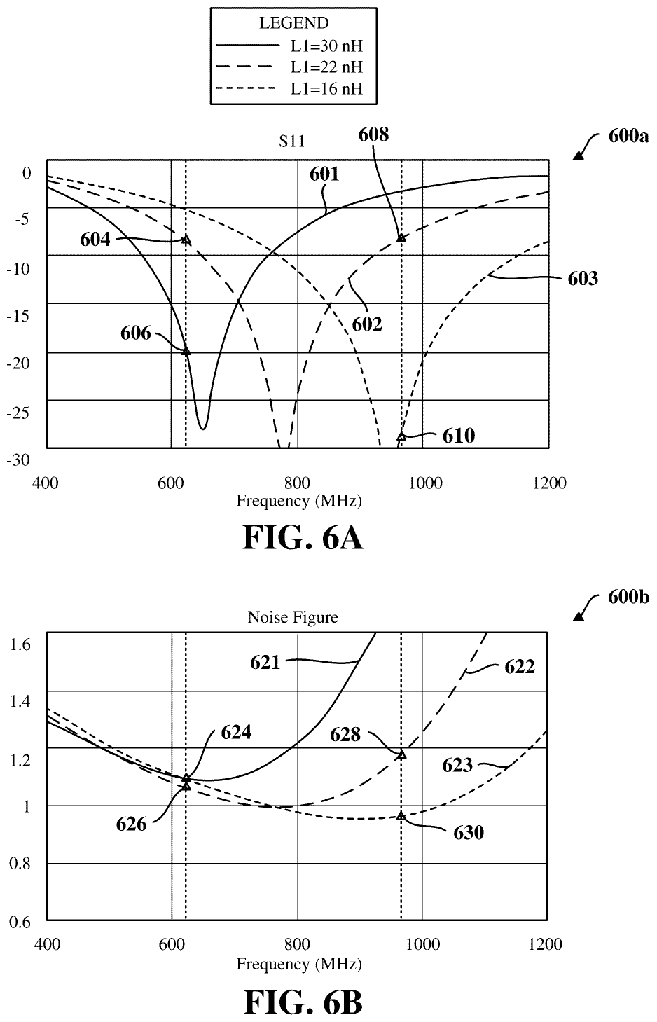

Between the input of the low noise amplifier 510 and the output (labeled SWO) of the M:1 switch matrix 506 is the matching network 509. The configuration of FIG. 5 may optimize size and cost as many filters (e.g., the six filters of the plurality of bandpass filters 504) are coupled to the M:1 switch matrix 506, and the matching network 509 includes a series-only inductor 511. The series-only inductor 511 may be a lumped element, integrated element, or any combination thereof. In the example of FIG. 5, the plurality of bandpass filters 504 shares the same matching network 509 (i.e., the series-only inductor 511). A single series-only inductor 511 necessarily has a given frequency dependence, and selectivity may be problematic for this configuration. For example, the value of inductance that offers the best performance for band n8 may not provide a similarly best performance for band n71. Accordingly, tradeoffs in performance versus frequency may be required, as shown in FIGS. 6A and 6B.

FIGS. 6A and 6B are plots of S11 600a and noise FIG. 600b, respectively, for the series-only inductor 511 of the matching network 509, as shown and described in connection with FIG. 5. The direction of the S11 600a measurement is illustrated in FIG. 5. Plots of S11 for an inductor value of 30 nH 601, 22 nH 602, and 16 nH 603 are provided in FIG. 6A. Plots of noise figure for the inductor value of 30 nH 621, 22 nH 622, and 16 nH 623 are provided in FIG. 6B. As shown in FIG. 6A, an inductance of 16 nH provides a deep null of −29.36 dB at 960 MHz (see marker 610) in the n8 band. As shown in FIG. 6B, the inductance of 16 nH also provides a minimum noise figure of 0.9631 at 960 MHz (see marker 630), also in the n8 band.

In contrast, as shown in FIG. 6A, an inductance of 30 nH provides an S11 of −19.14 dB at 617 MHz (see marker 606) in the n71 band. As shown in FIG. 6B, the inductance of 30 nH provides a noise figure of 1.102 dB at 617 MHz (see marker 624) in the n71 band.

As a compromise value, to try to obtain the best performance from the n71 to the n8 bands, an inductance of 22 nH may be selected. As shown in FIG. 6A, the compromise value of 22 nH provides an S11 of −8.15 dB at 617 MHz (see marker 604) in the n71 band and −8.162 dB at 960 MHz (see marker 608) in the n8 band. While this may be adequate matching for all bands (from n71 to n8), the noise figure of the system suffers at the higher frequencies, rising from 0.9631 dB at 960 MHz (see marker 630) utilizing the 16 nH inductor to 1.163 dB at 960 MHz (see marker 628) utilizing the 22 nH inductor. There is a slight improvement in noise figure observed at 617 MHz, dropping from 1.102 dB for both 30 nH and 16 nH at 617 MHz (see marker 624) to 1.07 dB at 617 MHz (see marker 626) using the compromise value of 22 nH.

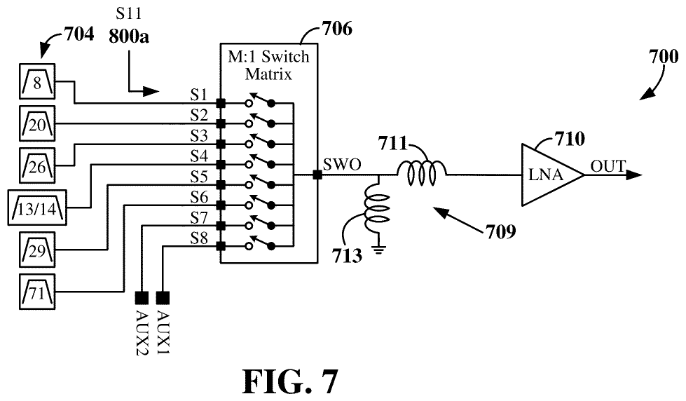

FIG. 7 is a simplified schematic drawing of a plurality of bandpass filters 704, an M:1 switch matrix 706 (e.g., a preselection switch bank), a matching network 709, and a low noise amplifier 710 according to some aspects of the disclosure. The plurality of bandpass filters 704 may be similar to the plurality of bandpass filters 204, 404, 504, as shown and described in connection with FIGS. 2, 4, and 5, respectively. The M:1 switch matrix 706 may be similar to the M:1 switch matrix 206, 406, 506, as shown and described in connection with FIGS. 2, 4, and 5, respectively. The low noise amplifier 710 may be similar to the low noise amplifier 210, 410, and 510, as shown and described in connection with FIGS. 2, 4, and 5, respectively. Detailed descriptions of the plurality of bandpass filters 704, the M:1 switch matrix 706, and the low noise amplifier 710 are omitted to reduce duplication and for the sake of brevity.

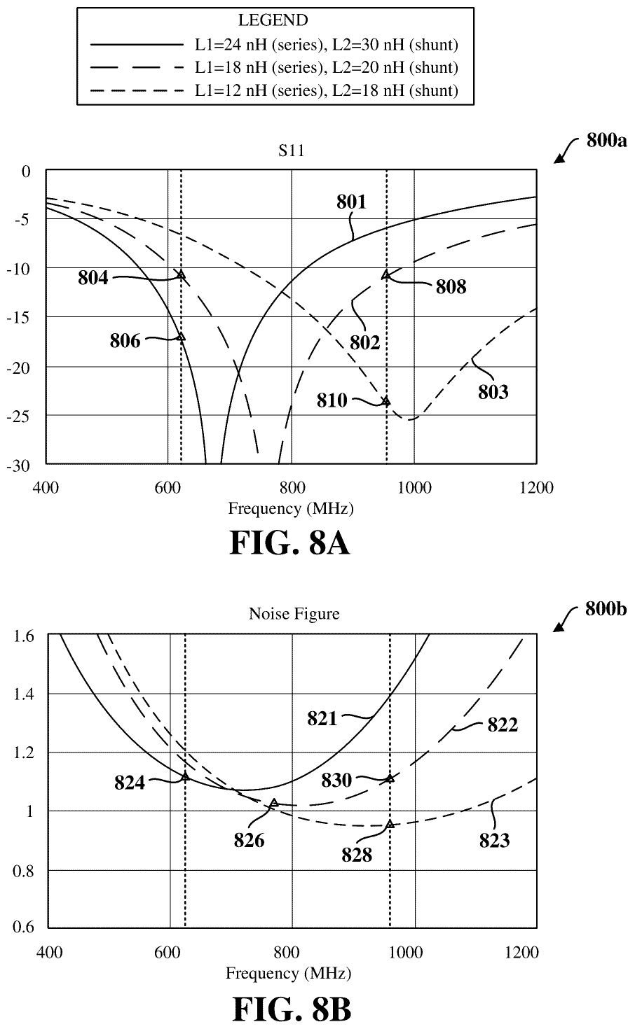

The matching network 709 is positioned between the output (labeled SWO) of the M:1 switch matrix 706 and the low noise amplifier 710 input. The configuration of FIG. 7, like FIG. 5, may optimize size and cost as many filters (e.g., the six filters of the plurality of bandpass filters 704) are coupled to the M:1 switch matrix 706 and the matching network 709 includes a shunt-series pair of inductors 713, 711, respectively. Similar to the example of FIG. 5, the shunt-series pair of inductors 713, 711 may be lumped elements or distributed elements or any combination thereof. In the example of FIG. 7, the plurality of bandpass filters 704 shares the same matching network 709 (i.e., the shunt-series pair of inductors 713, 711). As with the series-only inductor 511, the shunt-series pair of inductors 713, 711 necessarily has a given frequency dependence, and selectivity may be problematic for this configuration. Again, by way of example, the values of inductance that offer the best performance for band n8 may not provide a similarly best performance for band n71. Accordingly, tradeoffs in performance versus frequency may be required, as shown in FIGS. 8A and 8B.

FIGS. 8A and 8B are plots of S11 800a and noise FIG. 800b, respectively, for a shunt-series pair of inductors 713, 711 of the matching network 709 as shown and described in connection with FIG. 7. The direction of the S11 800a measurement is illustrated in FIG. 7. Plots of S11 for the series and shunt combinations of 24 nH and 30 nH (trace 801), 18 nH and 20 nH (trace 802), and 12 nH and 18 nH (trace 803) are provided in FIG. 8A. Plots of noise figure for the series and shunt combinations of 24 nH and 30 nH (trace 821), 18 nH and 20 nH (trace 822), and 12 nH and 18 nH (trace 823) are provided in FIG. 8B. As shown in FIG. 8A, a series inductance of 12 nH and a shunt inductance of 18 nH provides a null in S11 of −24.7 dB at 900 MHz (see marker 810) in the n8 band. As shown in FIG. 8B, the series inductance of 12 nH and the shunt inductance of 18 nH also provides a minimum noise figure of 0.9575 at 960 MHz (see marker 828) also in the n8 band.

In contrast, as shown in FIG. 8A, a series inductance of 24 nH and a shunt inductance of 30 nH provides an S11 of −16.71 dB at 617 MHz (see marker 806) in the n71 band. As shown in FIG. 8B, the series inductance of 24 nH and a shunt inductance of 30 nH provide a noise figure of 1.12 dB at 617 MHz (see marker 824) in the n71 band.

As compromise values, to try to obtain the best performance from the n71 to the n8 bands, a series inductance of 18 nH and a shunt inductance of 20 nH may be selected.

As shown in FIG. 8A, the compromise value of the series inductance of 18 nH and the shunt inductance of 20 nH provides an S11 of −10.65 dB at 617 MHz (see marker 804) in the n71 band and −10.68 dB at 960 MHz (see marker 808) in the n8 band. While this may be adequate matching for all bands (from n71 to n8), and while the noise figure has a minimum of 1.02 dB at 768 MHz (see marker 826) (e.g., in the middle between 617 MHz and 960 MHz), the system's noise figure suffers at the higher frequencies, rising from 0.96 dB at 960 MHz (see marker 828) with a series inductance of 12 nH and a shunt inductance of 18 nH, to 1.12 dB at 960 MHz (see marker 830) with a series inductance of 18 nH and a shunt inductance of 20 nH.

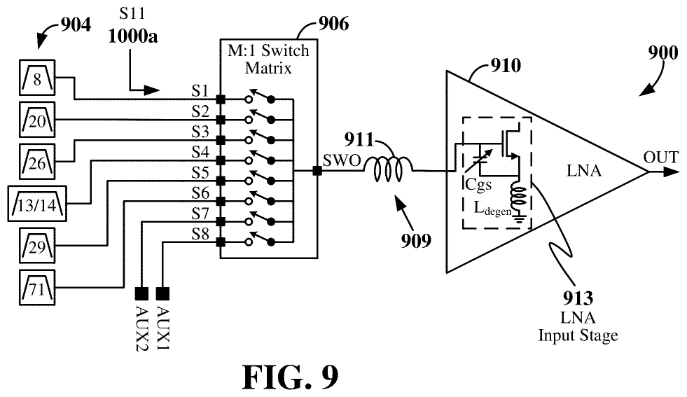

FIG. 9 is a simplified schematic drawing of a plurality of bandpass filters 904, an M:1 switch matrix 906, a matching network 909, and a low noise amplifier 910 according to some aspects of the disclosure. The plurality of bandpass filters 904 may be similar to the plurality of bandpass filters 204, 404, 504, 704, as shown and described in connection with FIGS. 2, 4, 5, and 7, respectively. The M:1 switch matrix 906 may be similar to the M:1 switch matrix 206, 406, 506, and 706, as shown and described in connection with FIGS. 2, 4, 5, and 7, respectively. The low noise amplifier 910 may be similar to the low noise amplifier 210, 410, 510, and 710, as shown and described in connection with FIGS. 2, 4, 5, and 7, respectively. Detailed descriptions of the plurality of bandpass filters 904, the M:1 switch matrix 906, and the low noise amplifier 910 are omitted to reduce duplication and for the sake of brevity.

The matching network 909 is between the output (labeled SWO) of the M:1 switch matrix 906 and the low noise amplifier 910 input. The configuration of FIG. 9 may optimize size and cost as many filters (e.g., the six filters of the plurality of bandpass filters 904) are coupled to the M:1 switch matrix 906, and the matching network 909 includes a series-only inductor 911. The series-only inductor 911 may be a lumped element, distributed element, or any combination thereof. In the example of FIG. 9, the plurality of bandpass filters 904 share the same matching network 909 (i.e., the series-only inductor 911).

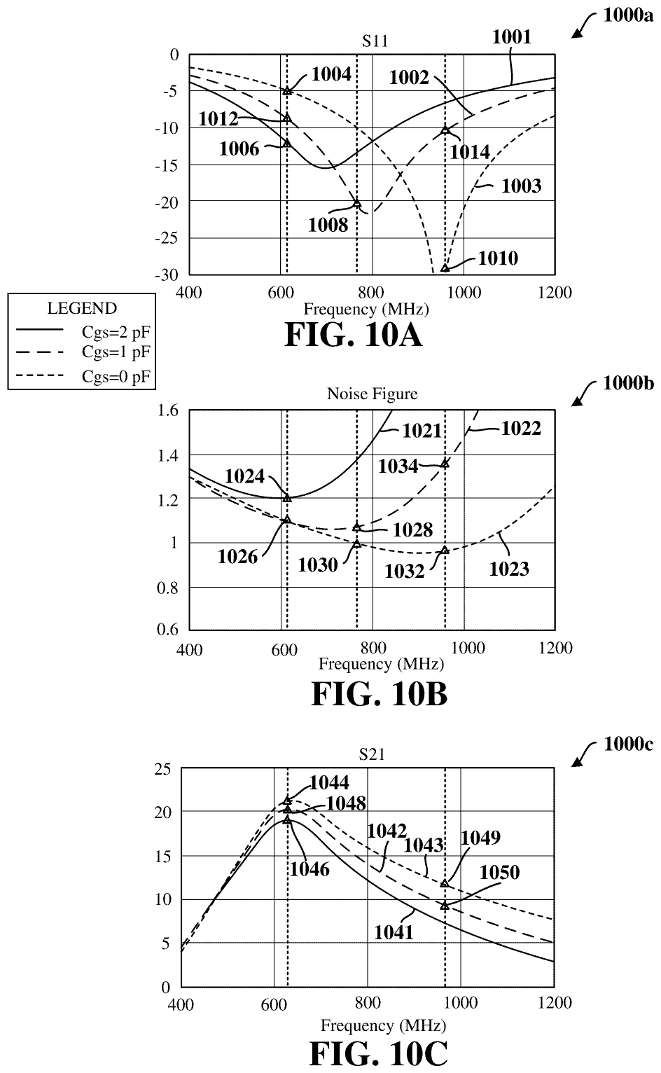

In the example of FIG. 9, a tunable capacitor (Cgs) is present in low noise amplifier 910 input stage 913. The tunable capacitor enables additional tuning for impedance matching in the frequency domain. Still, there is a degradation in noise figure and gain (as measured by the S-parameter S21 (as shown in FIG. 10C)) at lower frequencies as the value of Cgs is increased.

FIGS. 10A, 10B, and 10C are graphs of S11 1000a, noise FIGS. 1000b, and S21 1000c as a function of Cgs, as Cgs is swept from 0 pF to 2 pF and the series-only inductor 911 is maintained at 16 nH for the matching network 909 as shown and described in connection with FIG. 9. The direction of the S11 1000a measurement is illustrated in FIG. 9. Plots of S11 for Cgs=2 pF (trace 1001), 1 pF (trace 1002), and 0 pF (trace 1003) are provided in FIG. 10A. Plots of noise figure for Cgs=2 pF (trace 1021), 1 pF (trace 1022), and 0 pF (trace 1023) are provided in FIG. 10B. Plots of S21 for Cgs=2 pF (trace 1041), 1 pF (trace 1042), and 0 pF (trace 1043) are provided in FIG. 10C.

As shown in FIG. 10A, the inductance of 16 nH with Cgs of 0 pF provides a deep null in S11 of −29.3 dB at 960 MHz (see marker 1010) in the n8 band. (See also marker 1004 showing an S11 of −5 dB at 617 MHz.) As shown in FIG. 10B, the inductance of 16 nH with Cgs of 0 pF also provides a minimum noise figure of 0.98 at 960 MHz (see marker 1032) in the n8 band. As shown in FIG. 10C, the inductance of 16 nH with Cgs of 0 pF provides a gain of 12 dB at 960 MHz (see marker 1049) in the n8 band.

In contrast, as shown in FIG. 10A, an inductance of 16 nH with Cgs of 2 pF, provides an S11 of −12.3 dB at 617 MHz (see marker 1006) in the n71 band. As shown in FIG. 10B, the inductance of 16 nH with Cgs of 2 pF also provides a minimum noise figure of 1.18 dB at 617 MHz (see marker 1024) in the n71 band. As shown in FIG. 10C, the inductance of 16 nH with Cgs of 2 pF provides an S21 (i.e., gain) of 19.2 dB at 617 MHz (see marker 1046) in the n71 band.

As a compromise value, to try to obtain the best performance from the n71 to the n8 bands, the inductance is maintained at 16 nH, and the Cgs of 1 pF is provided. For the tuning technique using Cgs, the value of Cgs does not have to be fixed (e.g., different values of Cgs for n8 and n71 may be set). The main drawback to this method of tuning Cgs is that increasing Cgs decreases S21. An S11 of −8 dB at 617 MHz (see marker 1012) in the n71 band and −10.5 dB at 960 MHz (see marker 1014) in the n8 band is realized at these values. (See also marker 1008 S11 of −20 at 768 MHz.) In FIG. 10B, the noise figure of the system suffers at the higher frequencies, rising from 0.98 dB at 960 MHz (see marker 1032) for a Cgs of 0 pF to 1.35 dB at 960 MHz (see marker 1034) for Cgs of 1 pF. In FIG. 9C, the value of S21 for a Cgs of 1 pF is about 20 dB at 617 MHz (see marker 1048) and drops to 9 dB at 960 MHz (see marker 1050). At 617 MHz, as the capacitance is swept from 0 to 2 pF, the value of S21 drops from 21 dB (see marker 1044) to 19 dB (see marker 1046). See also marker 1024 corresponding to a noise figure of 1.2 at 617 MHz, marker 1026 corresponding to a noise figure of 1.1 at 617 MHz, marker 1028 corresponding to a noise figure of 1.05 at 768 MHz, marker 1030 corresponding to a noise figure of 1.08 at 767 MHZ.

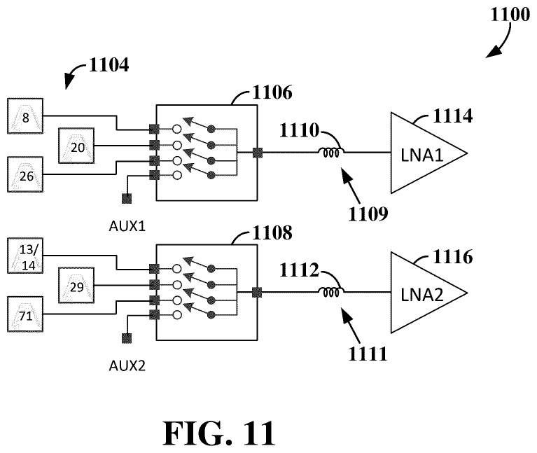

FIG. 11 is a simplified schematic drawing 1100 of a plurality of bandpass filters 1104, a first switch matrix 1106, a second switch matrix 1108, a first series-only inductor 1110, a second series-only inductor 1112, a first low noise amplifier 1114, and a second low noise amplifier 1116 according to some aspects of the disclosure. In the simplified schematic drawing 1100 of FIG. 11, both the first low noise amplifier 1114 and the second low noise amplifier 1116 each with a respective first matching network 1109 (e.g., the first series-only inductor 1110) and a second matching network 1111 (e.g., the second series-only inductor 1112) must be used. Dividing the plurality of bandpass filters 1104 between the first switch matrix 1106 and the second switch matrix 1108 may offer some performance optimization. However, each of the first matching network 1109 and the second matching network 1111 are fixed and cannot be reconfigured (i.e., the first matching network 1109 is limited to the first series-only inductor 1110 and the second matching network 1111 is limited to the second series-only inductor 1112 (or some other fixed and non-configurable configurations of matching components)). Once manufactured, each respective matching network configuration's type and value(s) is unchangeable. For example, changing the value of inductance of the first matching network 1109 (e.g., from a first value of series inductance to a second value of series inductance), or changing the series-only configuration of the second matching network 1111 (e.g., from a series-only to a shunt-series configuration) is not possible.

Additionally, any amount of performance optimization associated with the circuits exemplified in the simplified schematic drawing 1100 of FIG. 11 comes with the price of an increase in circuit footprint, the addition of connection points or bumps, and the increased cost (in terms of money and system power consumed) in view of the use of two low noise amplifiers and two matching networks in comparison to, for example, the circuits of FIGS. 5, 7, and 9.

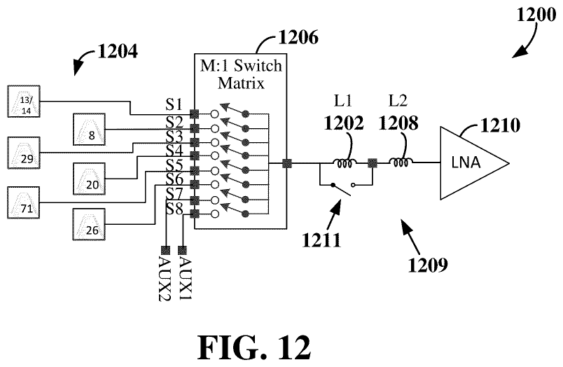

FIG. 12 is a simplified schematic drawing 1200 of a plurality of bandpass filters 1204, a switch matrix 1206, a first series inductor 1202 (L1) in series with a second series inductor 1208 (L2), a bypass circuit 1211 to short circuit the first series inductor 1202, and a low noise amplifier 1210, according to some aspects of the disclosure. The first series inductor 1202 (in conjunction with the bypass circuit 1211) and the second series inductor 1208 may be referred to as a matching network 1209. In the example of FIG. 12, the value of the series inductance of the matching network 1209 may be changed by short-circuiting the first series inductor 1202 by closing the switch of the bypass circuit 1211. When short-circuited, the inductance of the first series inductor 1202 essentially drops to zero. Changing the series inductance changes the impedance of the matching network 1209 by reducing the total inductance from L1+L2 to 0+L2. However, implementation of the bypass circuit 1211 comes with the cost of an increase in noise figure (˜0.2 dB) due to the addition of the switch in the bypass circuit 1211. Also, real estate loss in the form of at least an addition of one extra bump compared to implementations without the bypass circuit 1211, may be a drawback to the matching network 1209 represented in the simplified schematic drawing 1200 of FIG. 12.

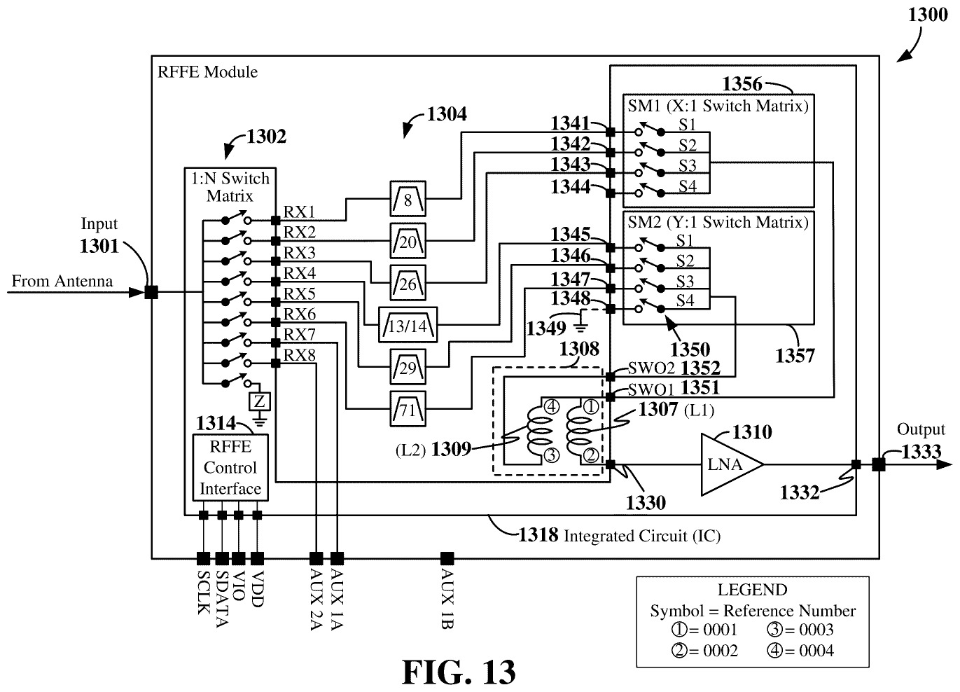

FIG. 13 is a simplified schematic drawing of an RF front-end (RFFE) module 1300 according to some aspects of the disclosure. The RFFE module 1300 may include an RFFE control interface 1314. The RFFE control interface may control, or interface with a controller that controls the configurations of (i.e., opens or closes) the pluralities of switches of the RFFE module 1300. The RFFE module 1300 may include an example of a configurable low noise amplifier input matching network, according to some aspects of the disclosure. In the non-limiting example of FIG. 13, the RFFE module 1300 includes a preselector.

The preselector may include a 1:N switch matrix 1302 (e.g., an input multiplexer of the preselector) and a plurality of bandpass filters 1304 coupled to respective outputs of the 1:N switch matrix 1302. The plurality of bandpass filters 1304 may be respectively tuned (for example and not limitation) to 5G NR channels (from highest to lowest center frequency) n8, n20, n26, n13/14, n29, and n71. The preselector may also include at least two output switch matrixes (e.g., output demultiplexers of the preselector). A first (labeled SM1) of the two output switch matrixes may be referred to herein as a first plurality of switches 1356, having a respective first plurality of input nodes 1341, 1342, 1343, 1344, and a first common output node 1351 (labeled SWO1). A second (labeled SM2) of the two output switch matrixes may be referred to herein as a second plurality of switches 1357, having a respective second plurality of input nodes 1345, 1346, 1347, and a second common output node 1352 (SWO2). Additional output switch matrixes (i.e., additional pluralities of switches) are within the scope of the disclosure.

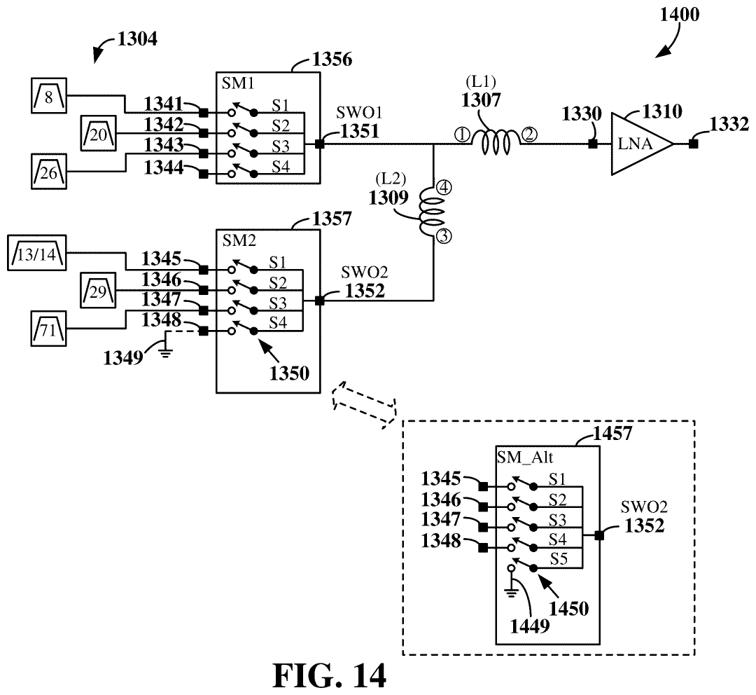

Not all of the input nodes of the first plurality of switches 1356 and the second plurality of switches 1357 (e.g., the output demultiplexers of the preselector) are necessarily coupled to an output of a respective bandpass filter. In the example of FIG. 13, a termination switch 1350 may be associated with the a fourth input node 1348 of the second plurality of switches 1357 and may be coupled to a termination 1349 (which may be optional) via the fourth input node 1348. In some examples, the termination switch 1350 may be an unused or auxiliary switch associated with a given plurality of switches. In the example of FIG. 13, the termination switch 1350 is identified as SM2-S4. In the example of FIG. 14, the termination switch 1450 is identified as SM_Alt-S5.

In some examples herein, the second plurality of switches 1357 may be identified as switches SM2-S1, SM2-S2, and SM2-S3, which may be distinct from the termination switch 1350, which may be identified as switch SM2-S4. The termination switch 1350, if present, may be associated with switches other than the second plurality of switches 1357 and continue to be within the scope of the disclosure.

As mentioned, the first plurality of switches 1356 and the second plurality of switches 1357 may operate as a first demultiplexer (e.g., an X:1 switch matrix) and a second demultiplexer (e.g., a Y:1 switch matrix) of the preselector, respectively. In the example of FIG. 13, N (associated with the 1:N switch matrix 1302), X, and Y are non-zero positive integers; N is greater than or equal to X+Y; X may be less than, equal to, or greater than Y. The first plurality of input nodes 1341, 1342, 1343 of the first plurality of switches 1356 are coupled to the bandpass filters' outputs tuned to channels n8, n20, and n26, respectively. The second plurality of input nodes 1345, 1346, 1347 of the second plurality of switches 1357 are coupled to the bandpass filters' outputs tuned to channels n13/14, n29, and n71, respectively.

The RFFE module 1300 may also include a termination 1349 (which may be optional). In the example of FIG. 13, the termination 1349 is depicted as a ground connection. Other terminations that are different from the ground connection (e.g., including other matching component(s)) are within the scope of the disclosure. In the example of FIG. 13, the termination 1349 is associated with the termination switch 1350. Closing or opening the termination switch 1350 connects or disconnects, respectively, the termination 1349 from at least the second common output node 1352.

In the example of FIG. 13, the termination 1349 is external to (e.g., not on the same substrate as or apart from) the second plurality of switches 1357. In some examples, the termination 1349 may be made integral with the second plurality of switches 1357 (see, for example, the alternative second plurality of switches 1457 and termination 1449 as shown and described in connection with FIG. 14). The termination 1349 may be associated with other switches, or made integral to other pluralities of switches, without departing from the scope of the disclosure.

The RFFE module 1300 may also include a low noise amplifier 1310 having a low noise amplifier input node 1330 and a low noise amplifier output node 1332. The frequency response of the low noise amplifier 1310 (e.g., the sole low noise amplifier in the example of FIG. 13) may support the entire frequency band of the RFFE module 1300. In the example of FIG. 13, the entire frequency band of the RFFE module 1300 spans between 5G NR channels n71 and n8 (i.e., spans a bandwidth of 343 MHz).

The RFFE module 1300 may also include a first matching component 1307 (L1) having a first node 0001 coupled to the first common output node 1351 and having a second node 0002 coupled to the low noise amplifier input node 1330. The RFFE module 1300 may also include a second matching component 1309 (L2) having a third node 0003 coupled to the second common output node 1352 (SWO2) and having a fourth node 0004 coupled to the first common output node 1351 (SWO1) and the first node of the first matching component 1307. In FIG. 13 and all following figures, the symbols (1), (2), (3), and (4) correspond to reference numbers 0001, 0002, 0003, and 0004, respectively. According to some aspects, the first matching component 1307 and the second matching component 1309, configured according to predetermined configurations of the first plurality of switches 1356, the second plurality of switches, and if present or used, a predetermined configuration of the termination switch 1350, may collectively form a matching network that matches the input impedance of the low noise amplifier input node 1330 to the output impedance of a given bandpass filter of the plurality of bandpass filters 1304 at the center frequency and over the bandwidth of the given bandpass filter.

In other words, to obtain the best performance (e.g., widest bandwidth, minimal reflection, maximum gain, lowest noise figure) from the low noise amplifier 1310 at each center frequency and bandwidth of a respective bandpass filter (i.e., where each bandpass filter is tuned to a respective center frequency and bandwidth of a given channel), the input impedance of the low noise amplifier at the center frequency and bandwidth of the respective bandpass filter, transformed back through a matching network 1308 and a respective closed switch (with all other switches of the first plurality of switches 1356 and the second plurality of switches 1357 are open) may be matched to an output impedance of the respective bandpass filter.

As observed above, because the input impedance of the low noise amplifier 1310 varies across the entire bandwidth of the low noise amplifier 1310, one fixed matching network (e.g., that includes lumped element(s) and/or distributed element(s)) may provide an acceptable result at some frequencies within the entire bandwidth but provide unacceptable results at other frequencies within the entire bandwidth.

Accordingly, apparatus and methods described herein may provide examples of a configurable low noise amplifier input matching network that may be reconfigured by changing the states of the first plurality of switches 1356, the states of the second plurality of switches 1357, and, if present and used with a termination 1349, by changing the state of the termination switch 1350. The reconfiguration may facilitate improved matching of the varied input impedance of the low noise amplifier 1310 over its bandwidth with the various output impedances of respective ones of the plurality of bandpass filters 1304 at each respective center frequency and bandwidth of each respective bandpass filter.

For example, in FIG. 13, the output impedance of the matching network 1308 (e.g., as seen looking into the second node of the first matching component 1307) may be changed based on the value, type, and orientation (all fixed in the example) of the first matching component 1307, the value, type, and orientation (all fixed in the example) of the second matching component 1309, the configuration of the first plurality of switches 1356, the configuration of the second plurality of switches 1357, and, if present and used with the termination 1349, the configuration of the termination switch 1350, according to some aspects of the disclosure.

In some examples, the first plurality of switches 1356 (SM1-S1, SM1-S2, SM1-S3, and/or SM1-S4) may selectively and respectively couple to corresponding ones of the plurality of bandpass filters 1304. The second plurality of switches 1357 (SM2-S1, SM2-S2, and SM3-S3) may selectively and respectively couple to other corresponding ones of the plurality of bandpass filters 1304. According to one alternative, the alternative second plurality of switches 1457 (SM_Alt-S1, SM_Alt-S2, SM_Alt-S3) may selectively and respectively couple to the other corresponding ones of the plurality of bandpass filters 1304. The second plurality of switches 1357 or the alternative second plurality of switches 1457 (of FIG. 14) may include a termination switch 1350, 1450, and the termination switch 1350, 1450 may couple to the termination 1349 of FIG. 13 or the termination 1449 of FIG. 14. Each of the just-recited switches is different from the others. In the examples, the just-recited switches are single-pole single-throw (SPST) switches. Other quantities, types, and organizations of switches are within the scope of the disclosure.

In the example of FIG. 13, the first plurality of switches 1356 with the first common output node 1351 and the second plurality of switches 1357 with the second common output node 1352 may be manufactured on one substrate without departing from the scope of the disclosure. Selective coupling of a given switch to a given bandpass filter, or selectively coupling the termination switch to the termination, may be made by operation (e.g., opening or closing, changing a state) of the given switch. In some examples, the RFFE control interface 1314 may configure the pluralities of switches of the RFFE module 1300.

In the example of FIG. 13, the first matching component 1307 is exemplified as a first inductor (L1) and the second matching component 1309 is exemplified as a second inductor (L2); however, the first matching component 1307 and the second matching component 1309 are not limited to inductors. In other examples, and throughout this disclosure, any matching component may be any lumped element (e.g., an inductor or a capacitor), any distributed element (e.g., a length of transmission line, a shorted or open stub of a transmission line), or any combination of lumped and/or distributed element(s), that transform a complex impedance (for example, as depicted on a Smith chart) from one value to another to, for example, effectuate the matching of a source impedance to a load impedance.

In FIG. 13, the 1:N switch matrix 1302, the RFFE control interface 1314, the low noise amplifier 1310, the first plurality of switches 1356 (e.g., SM1-S1, SM1-S2, SM1-S3, and/or SM1-S4), the second plurality of switches 1357 (e.g., SM2-S1, SM2-S2, and/or SM2-S3), and the termination switch 1350 (e.g., SM2-S4) are depicted as being included in an integrated circuit 1318; however, any organization of one or any combination of these components (e.g., on an IC and/or in a chip form) is within the scope of the disclosure. In FIG. 13, a connection between input node 1344 and input labeled AUX1B is omitted to avoid cluttering the drawing. It is noted that the RFFE module 1300 may include other elements (e.g., matching elements for the filters, electrostatic discharge protection, supply voltage filtering, etc.) that are not shown to avoid cluttering the drawing.

FIG. 14 is a simplified schematic drawing of a portion of the schematic of FIG. 13 according to some aspects of the disclosure. Like reference numbers in FIGS. 13 and 14 refer to the same or similar features and their descriptions will not be repeated to avoid duplication and for the sake of brevity. The portion of the schematic of FIG. 13 represented in FIG. 14 may be an example of a configurable low noise amplifier input matching network according to some aspects of the disclosure. The first matching component 1307 (L1) and the second matching component 1309 (L2) may be used in different configurations to match the input of the low noise amplifier 1310 to a respective output of a bandpass filter of the plurality of bandpass filters 1304. The changes to configuration may be accomplished by changing the states (e.g., the configurations) of the first plurality of switches 1356, the second plurality of switches 1357, and the termination switch 1350 (if present or used with the termination 1349).

In the example of FIG. 14, the second plurality of switches 1357 may be replaced with an alternative second plurality of switches 1457 as represented by the dashed-line double-headed arrow indicating an optional exchange (e.g., substitution) of the second plurality of switches 1357 with the alternative second plurality of switches 1457. The alternative second plurality of switches 1457 integrates a termination 1449 with the alternative second plurality of switches 1457 (e.g., the termination 1449 is on-board with the second plurality of switches 1457 as compared to the termination 1349). Additionally, in connection with the alternative second plurality of switches 1457, the node of the termination switch 1450 coupled to the termination 1449 is not accessible external to the alternative second plurality of switches 1457. Including the termination 1449 with the second plurality of switches 1457 and the termination switch 1450 may save real estate by avoiding a need to add a bump corresponding to the fifth switch (SM_Alt-S5) of the alternative second plurality of switches 1457.

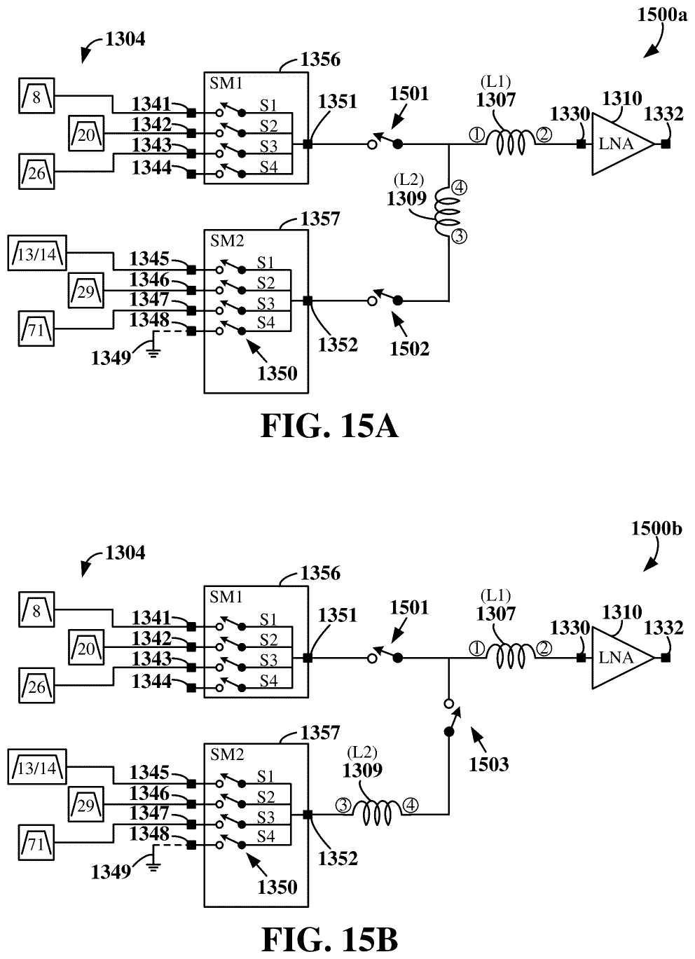

FIGS. 15A and 15B are first alternative 1500a and second alternative 1500b simplified schematic drawings of FIG. 14, according to some aspects of the disclosure. Like reference numbers in FIGS. 13, 14, and 15 refer to the same or similar features, and their descriptions will not be repeated to avoid duplication and for the sake of brevity.

In FIG. 15A, a first switch 1501 is coupled between the first common output node 1351 and a node shared by the first node 0001 of the first matching component 1307 and the fourth node 0004 of the second matching component 1309. In the example of FIG. 15A, in a case in which no switch coupled to the first plurality of input nodes 1341, 1342, 1343, 1344 of the first plurality of switches 1356 is to be configured in a closed state (e.g., the preselector is not configured to pass any signal on any channel corresponding to the bandpass filters for channels n8, n20, or n26), opening the first switch 1501 to present an open circuit to the node shared by the first node 0001 of the first matching component 1307 and the fourth node 0004 of the second matching component 1309 may result in less stray capacitance in comparison to opening all switches (e.g., SM1-S1, SM1-S2, SM1-S3, SM1-S4) to present the open circuit to the node shared by the first node 0001 of the first matching component 1307 and the fourth node 0004 of the second matching component 1309.

Similarly, in FIG. 15A, a second switch 1502 is coupled between the second common output node 1352 and the third node 0003 of the second matching component 1309. In the example of FIG. 15A, in a case in which no switch coupled to the second plurality of input nodes 1345, 1346, 1347 of the second plurality of switches 1357, or to the termination switch 1350, is to be configured in a closed state (e.g., the preselector is not configured to pass any signal on any channel corresponding to the bandpass filters for channels n13/14, n29, or n71 and the termination switch 1350 will not be configured to a closed state), opening the second switch 1502 to present an open circuit to the third node 0003 of the second matching component 1309 may result in less stray capacitance in comparison to opening all switches (e.g., SM2-S1, SM2-S2, SM2-S3, SM2-S4) to present the open circuit to the third node 0003 of the second matching component 1309.

In FIG. 15B, the first switch 1501 remains in the same location as in FIG. 15A. A third switch 1503 is located between the first node 0001 of the first matching component 1307 and the fourth node 0004 of the second matching component 1309. As in the example of FIG. 15A, in a case in which no switch coupled to the first plurality of input nodes 1341, 1342, 1343, 1344 of the first plurality of switches 1356 is to be configured in a closed state (e.g., the preselector is not configured to pass any signal on any channel corresponding to the bandpass filters for channels n8, n20, or n26), opening the first switch 1501 to present an open circuit to the node shared by the first node 0001 of the first matching component 1307 and the fourth node 0004 of the second matching component 1309 may result in less stray capacitance in comparison to opening all switches (e.g., SM1-S1, SM1-S2, SM1-S3, SM1-S4) to present the open circuit to the node shared by the first node 0001 of the first matching component 1307 and the fourth node 0004 of the second matching component 1309.

Similarly, in FIG. 15B, in a case in which no switch coupled to the second plurality of input nodes 1345, 1346, 1347 of the second plurality of switches 1357, or to the termination switch 1350, is to be configured in a closed state (e.g., the preselector is not configured to pass any signal on any channel corresponding to the bandpass filters for channels n13/14, n29, or n71 and the termination switch 1350 will not be configured to a closed state), opening the third switch 1503 to present an open circuit to the fourth node 0004 of the second matching component 1309 may result in less stray capacitance in comparison to opening all switches (e.g., SM2-S1, SM2-S2, SM2-S3, SM2-S4) to present the open circuit to the fourth node 0004 of the second matching component 1309.

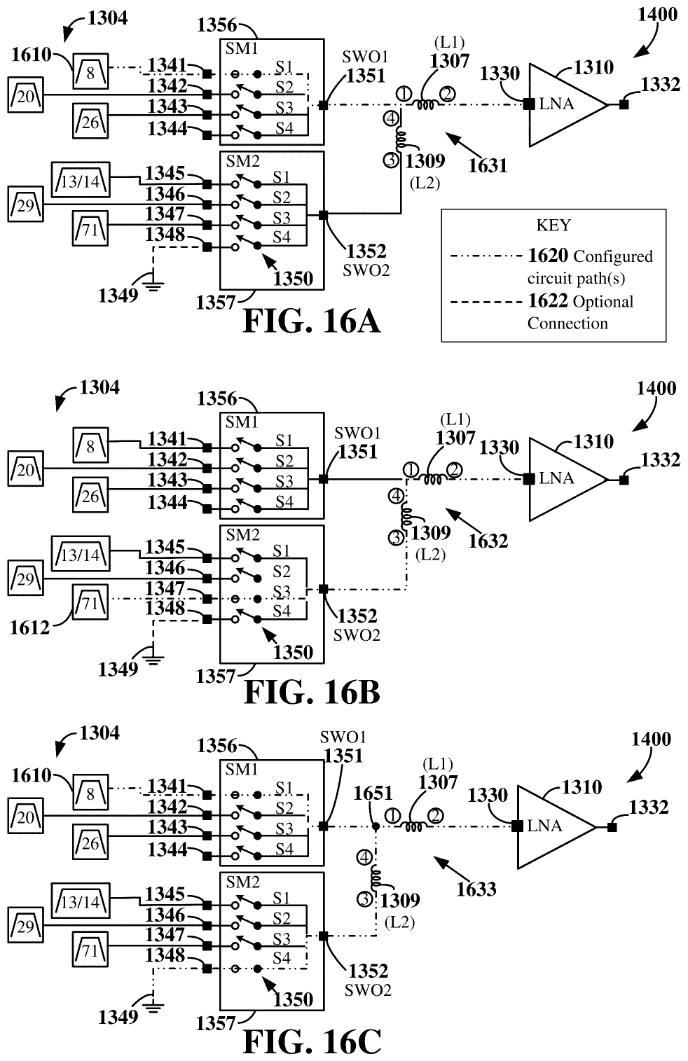

FIGS. 16A, 16B, and 16C show three instantiations of the apparatus 1400 of FIG. 14 according to some aspects of the disclosure. Like reference numbers in FIGS. 13, 14, and 16 refer to the same or similar features, and their descriptions will not be repeated to avoid duplication and for the sake of brevity.

Each of the three instantiations is obtained by changing the states (e.g., between an open state and a closed state) of the first plurality of switches 1356, the second plurality of switches 1357, and the termination switch 1350 (in connection with FIG. 16C). In other words, the hardware, including the plurality of bandpass filters 1304, the first plurality of switches 1356, the second plurality of switches 1357, the termination switch 1350 (if used in connection with the termination 1349), the first matching component 1307, the second matching component 1309, and the low noise amplifier 1310 does not change from instantiation to instantiation (except for the state changes of the first plurality of switches 1356, the second plurality of switches 1357, and the termination switch 1350).

The apparatus 1400 of FIGS. 16A, 16B, and 16C utilize the second plurality of switches 1357 as described and shown in connection with FIGS. 13 and 14; however, the alternative second plurality of switches 1447 (of FIG. 14) may be used in place of the second plurality of switches 1357 without departing from the scope of the disclosure. The three instantiations of FIGS. 16A, 16B, and 16C are representative examples of an operating configurable low noise amplifier input matching network according to some aspects of the disclosure. The dash-double-dot lines 1620 of FIGS. 16A, 16B, and 16C identify the circuit paths configured in each instantiation according to some aspects of the disclosure. The dashed lines 1622 associated with the termination 1349 of FIGS. 16A and 16B identify optional connections according to some aspects of the disclosure.

Each of the instantiations of the apparatus 1400, as represented in FIGS. 16A, 16B, and 16C, includes a first plurality of switches 1356 having a respective first plurality of input nodes 1341, 1342, 1343, 1344 and a first common output node 1351, a second plurality of switches 1357 having a respective second plurality of input nodes 1345, 1346, 1347 and a second common output node 1352, a termination switch 1350 (shown in conjunction with a termination 1349 in FIGS. 16A and 16B (as optional) and in conjunction with the termination 1349 in FIG. 16C (in use)), a low noise amplifier 1310 having the low noise amplifier input node 1330 and a low noise amplifier output node 1332, a first matching component 1307 having a first node 0001 coupled to the first common output node 1351 and having a second node 0002 coupled to the low noise amplifier input node 1330, and a second matching component 1309 having a third node 0003 coupled to the second common output node 1352 and having a fourth node 0004 coupled to the first common output node 1351 and the first node 0001, where at least two matching network configurations of the first matching component and the second matching component may be obtained by configuring respective states of the first plurality of switches and the second plurality of switches. The configured state of a given switch of the first plurality of switches and the second plurality of switches may be, for example, either an open state or a closed state.

Each instantiation also illustrates a first plurality of radio frequency (RF) filters (e.g., bandpass filters), corresponding to channels n8, n20, and n26 of the plurality of bandpass filters 1304, respectively coupled to the first plurality of input nodes 1341, 1342, 1343. Each instantiation also illustrates a second plurality of radio frequency (RF) filters (e.g., bandpass filters), corresponding to channels n13/14, n29, and n71 of the plurality of bandpass filters 1304, respectively coupled to the second plurality of input nodes 1345, 1346, 1347. Furthermore, in each instantiation, the first matching component 1307 is represented as a first inductor. The second matching component 1309 is represented as a second inductor. The first inductor has a first value of inductance. The second inductor has a second value of inductance. The first value of inductance and the second value of inductance are both greater than zero. The first value is greater than, equal to, or less than the second value. Although represented as inductors, nothing in the disclosure limits the first matching component 1307 and/or the second matching component 1309 to being an inductor. Neither the first matching component 1307 nor the second matching component 1309 is exemplified with a bypass circuit (e.g., a circuit that short circuits the matching component to reduce its value to zero effectively) as such bypass circuits may adversely affect the performance of the apparatus 1400 (e.g., by increasing noise figure).

In the first instantiation of FIG. 16A, a first switch (e.g., switch SM1-S1) of the first plurality of switches 1356 corresponding to a first input node (e.g., first input node 1341) of the first plurality of input nodes 1341, 1342, 1343, 1344, is configured in a closed state. The remaining switches (e.g., switches SM1-S2, SM1-S3, SM1-S4) of the first plurality of switches 1356 are each configured in an open state, as shown. By configuring the first switch (e.g., switch SM1-S1) in the closed state, the first bandpass filter 1610 (e.g., associated with channel n8) of the plurality of bandpass filters 1304 is coupled to the low noise amplifier 1310 via the first matching network 1631 of the apparatus 1400. Signals in the bandwidth of the first bandpass filter 1610, received at an antenna (not shown) of a device (not shown), pass through the first bandpass filter 1610 and are amplified by the low noise amplifier 1310. Signals outside of the bandwidth of the first bandpass filter 1610, received at the antenna (not shown) of the device (not shown), are applied to the first bandpass filter 1610 but are attenuated according to the characteristics of the first bandpass filter 1610. The attenuated signals may still reach the low noise amplifier 1310. Still, their attenuated nature reduces any adverse effect they may have after their amplification, if any, by the low noise amplifier 1310. The first instantiation may have utility in a mid-frequency region.

Returning to the first instantiation of FIG. 16A, each of the second plurality of switches 1357 (e.g., SM2-S1, SM2-S2, SM2-S3) (and the termination switch 1350 (e.g., SM2-S4) associated with the second plurality of switches 1357) is configured in an open state and collectively present an open circuit to the third node 0003 of the second matching component 1309. The open circuit at the third node 0003 of the second matching component 1309 results in no current passing through the second matching component 1309, effectively and functionally removing the second matching component 1309 from the first matching network 1631.

Furthermore, according to the first instantiation of the apparatus 1400 of FIG. 16A, the first matching network 1631 of the apparatus 1400 may correspond to the first matching component 1307 coupled in series between: the first input node 1341 of the first plurality of input nodes 1341, 1342, 1343, 1344, and the low noise amplifier input node 1330.

Nevertheless, in the first instantiation of FIG. 16A, the second matching component 1309, in combination with the open second plurality of switches 1357, may present undesired parasitics (e.g., undesired inductance or capacitance) to the first matching network 1631. As illustrated in FIGS. 15A and 15B, described above, the parasitics may be reduced or eliminated by adding the second switch 1502 and/or the third switch 1503 to the first matching network 1631 and configuring the second switch 1502 and/or the third switch 1503 in an open state (in the instantiation depicted in FIG. 16A).

With the second switch 1502 added to the first matching network 1631 and configured in an open state as shown in FIG. 15A, the third node 0003 of the second matching component 1309 is presented with an open circuit between the third node 0003 of the second matching component 1309 and the open circuits (of the open switches) of the second plurality of switches 1357 and the termination switch 1350. The configuration of the second switch 1502 in FIG. 15A at least reduces or eliminates the parasitics associated with the presence of the second plurality of switches 1357 and the termination switch 1350.

With the third switch 1503 added to the first matching network 1631 and configured in an open state as shown in FIG. 15B, the node previously shared by the fourth node 0004 of the second matching component 1309, the first node 0001 of the first matching component 1307, and the first common output node 1351 is presented with an open circuit (instead of being presented with the second matching component 1309 in series with the open circuits of the second plurality of switches 1357 and the termination switch 1350). The configuration of the third switch 1503 in FIG. 15B at least reduces or eliminates the parasitics associated with the presence of the second matching component 1309 in series with the open circuits of the second plurality of switches 1357 and the termination switch 1350.

In some examples, the noise factor performance of the first matching network 1631 (a series-only matching network) and the third matching network 1633 (a shunt-series matching network) may be compared and the matching network that provides the best noise figure (i.e., the lowest value of noise factor) may be selected to optimize performance.

Turning now to the second instantiation of the apparatus 1400, as shown in FIG. 16B, each of the first plurality of switches 1356 (e.g., SM1-S1, SM1-S2, SM1-S3, SM1-S4) is configured in an open state and collectively presents an open circuit to the first node 0001 of the first matching component 1307 and the fourth node 0004 of the second matching component 1309. A first switch (e.g., SM2-S3) of the second plurality of switches 1357 corresponding to a first input node 1347 of the second plurality of input nodes 1345, 1346, 1347 is configured in a closed state, and each remaining switch (SM2-S1, SM2-S2) of the second plurality of switches (and the termination switch 1350 (e.g., SM2-S4) associated with the second plurality of switches 1357) is configured in an open state. It is noted that any switch (including switch SM2-S3) of the second plurality of switches 1357 may be referred to as the “first switch” for ease of explanation in connection with the description of this second instantiation of FIG. 16B.

By configuring the first switch (e.g., switch SM2-S3, where any of the switches of the second plurality of switches may be referred to as the “first switch”) in the closed state, the sixth bandpass filter 1612 (e.g., corresponding to channel n71) of the plurality of bandpass filters 1304 is coupled to the low noise amplifier 1310 via the second matching network 1632 of the apparatus 1400. Signals in the bandwidth of the sixth bandpass filter 1612, received at the antenna (not shown) of the device (not shown), pass through the sixth bandpass filter 1612 and are amplified by the low noise amplifier 1310. Signals outside the bandwidth of the sixth bandpass filter 1612, received at the antenna (not shown) of the device (not shown), are applied to the sixth bandpass filter 1612 but are attenuated according to the characteristics of the sixth bandpass filter 1612. The attenuated signals may still reach the low noise amplifier 1310. Still, their attenuated nature reduces any adverse effect they may have after their amplification, if any, by the low noise amplifier 1310.

Furthermore, according to the second instantiation of FIG. 16B, the second matching network 1632 of the apparatus 1400 corresponds to a series combination of the first matching component 1307 and the second matching component 1309 coupled between: the first input node 1347 of the second plurality of input nodes 1345, 1346, 1347, and the low noise amplifier input node 1330. It is noted that because the switch SM2-S3 of the second plurality of switches 1357 is referred to as the “first switch,” the input node corresponding to SM2-S3 is referred to as the first input node 1347 for ease of explanation in connection with the description of this second instantiation of FIG. 16B.

Nevertheless, in the second instantiation of FIG. 16B, the first plurality of switches (e.g., SM1-S1, SM1-S2, SM1-S3, SM1-S4), which are all in open states, may present undesired parasitics (e.g., undesired inductance or capacitance) to the second matching network 1632. As illustrated in FIGS. 15A and 15B, described above, the parasitics may be reduced or eliminated by adding the first switch 1501 to the second matching network 1632 and configuring the first switch 1501 in an open state (in the instantiation depicted in FIG. 16B).

With the first switch 1501 added to the second matching network 1632 and configured in an open state as shown in FIGS. 15A and 15B, the node shared by the first node 0001 of the first matching component 1307 and the fourth node 0004 of the second matching component 1309 is presented with an open circuit between the shared node and the open circuits (of the open switches) of the first plurality of switches 1356. The configuration of the first switch 1501 in FIG. 15A at least reduces or eliminates the parasitics associated with the presence of the first plurality of switches 1356 (each in an open state).

In consideration of FIGS. 15A and 15B and the discussions above, in some examples, the apparatus 1400 of FIGS. 16A, 16B, and 16C may also include at least one of: a first switch 1501 coupled between the first common output node 1351 and a node shared by the first node 0001 of the first matching component 1307 and the fourth node 0004 of the second matching component 1309; a second switch 1502 coupled between the second common output node 1352 and the third node 0003 of the second matching component 1309; or a third switch 1503 coupled between the fourth node 0004 of the second matching component 1309 and the node shared by the first node 0001 of the first matching component 1307 and the fourth node 0004 of the second matching component 1309.

Turning now to the third instantiation of FIG. 15C, it is noted that, for this third instantiation, the termination 1349 is present and in use. Accordingly, the apparatus 1400 may further include the termination 1349, and the termination switch 1350 may be configured to present an open circuit at the second common output node 1352 or a short circuit (to the termination 1349) at the second common output node 1352. As shown in the example of FIG. 16C, the termination switch 1350 may be integral to (e.g., included with, packaged with) the second plurality of switches 1357, and the termination 1349 may be external to the second plurality of switches 1357.

According to the third instantiation of FIG. 16C, a first switch (e.g., switch SM1-S1) of the first plurality of switches 1356 is configured in a closed state. Each remaining switch (e.g., SM1-S2, SM1-S3, SM1-S4) of the first plurality of switches 1356 is configured in an open state. Each switch (e.g., SM2-S1, SM2-S2, SM2-S3) of the second plurality of switches 1357 is configured in an open state. The termination switch 1350 (e.g., SM2-S4) is configured in a closed state. Furthermore, a matching network (i.e., the third matching network 1633) of the apparatus 1400 corresponds to the second matching component 1309, coupled in shunt between a shared node 1651 (the shared node 1651 comprising the first common output node 1351, the fourth node 0004 of the second matching component 1309, and the first node 0001 of the first matching component 1307) and the termination 1349 (via the termination switch 1350 coupled between the third node 0003 of the second matching component 1309 and the termination 1349). The first matching component 1307 is coupled in series between the shared node 1651 and the low noise amplifier input node 1330.

In summary, the first instantiation of the apparatus 1400 as shown in FIG. 16A corresponds to a configuration that includes a first bandpass filter 1610 of the plurality of bandpass filters 1304 and a first matching network 1631 (i.e., “series” as opposed to “series-series” matching network), where the only matching component actively used in the first instantiation is the first matching component 1307, according to some aspects of the disclosure.

The second instantiation of the apparatus 1400 as shown in FIG. 16B corresponds to a configuration that includes a sixth bandpass filter 1612 (corresponding to channel n71) of the plurality of bandpass filters 1304 and a second series-only (i.e., “series-series” as opposed to “series”) second matching network 1632 that includes the series combination of the first matching component 1307 and the second matching component 1309 coupled between the sixth bandpass filter 1612 and the low noise amplifier input node 1330, according to some aspects of the disclosure.

The third instantiation of the apparatus 1400 as shown in FIG. 16C corresponds to a configuration that includes the first bandpass filter 1610 of the plurality of bandpass filters 1304 and the third matching network 1633 according to some aspects of the disclosure. The first matching component 1307 is a first inductor having a first value of inductance, and the second matching component 1309 is a second inductor having a second value of inductance, where the first value of inductance and the second value of inductance are greater than zero and the first value is greater than, equal to, or less than the second value. Such a configuration may have a noise penalty (e.g., about 30-50 mdB of increased noise figure) due to added switch on-resistance. However, the total impact on the noise figure is partially compensated as there is less parasitic capacitance per a given plurality of switches (as a result of a lessened number of throws).

In one practical example, the second matching network 1632 may be utilized to provide adequate matching for lower frequency bands (e.g., 5G NR channel n71), while the third matching network 1633 may be utilized to provide adequate matching for higher frequency bands (e.g., 5G NR channel n8). For example, using a first matching component 1307 (L1) of 12 nH and a second matching component 1309 (L2) of 18 nH, and first configuring the apparatus 1400 in the second matching network 1632 configuration of FIG. 16B (i.e., a series-series configuration corresponding to a total series inductance of 12 nH+18 nH=30 nH), the low band frequency response of S11 and noise figure may be similar to the results illustrated in graphs of S11 600a and noise FIG. 600b of FIGS. 6A and 6B (which correspond to an optimal series-only configuration (i.e., 12 nH+18 nH=30 nH (series)) for the low frequency band of channel n71 (see traces 601 and 621 of FIGS. 6A and 6B)). Next, re-configuring the apparatus 1400 in the third matching network 1633 configuration of FIG. 16C (i.e., a shunt-series configuration), the high band frequency response of S11 and noise figure may be similar to the results illustrated in graphs of S11 800a and noise FIG. 800b of FIGS. 8A and 8B (which correspond to an optimal shunt-series configuration (i.e., 12 nH (series), 18 nH (shunt)) for the high frequency band of channel n8 (see traces 803 and 823 of FIGS. 8A and 8B).

In final notes relating to FIGS. 16A, 16B, and 16C, it has been observed that the first bandpass filter 1610 coupled to the first plurality of switches 1356 corresponds to the 5G NR band n8, and the sixth bandpass filter 1612 coupled to the second plurality of switches 1357 corresponds to the 5G NR band n71. It is noted that using the first bandpass filter 1610, in connection with explaining the first and third instantiations of FIGS. 16A and 16C, is for illustrative and non-limiting purposes; any filter coupled to any port of the first plurality of switches 1356 could be used in a similar example. It is also noted that using the sixth bandpass filter 1612, in connection with explaining the second instantiation of FIG. 16B, is for illustrative and non-limiting purposes; any filter coupled to any input port of the second plurality of switches 1357 could be used in a similar example.

Although the termination switch 1350 (SM2-S4) is depicted as being associated with the second plurality of switches 1357 (and the termination switch 1450 (SM_Alt-S5) is depicted as being associated with the alternative second plurality of switches 1457 (of FIG. 14)), the termination switch 1350, 1450 could be located anywhere that facilitates its operation. In the example of FIGS. 13, 14, 15A, 15B, 16A, 16B, and 16C, in a case where the termination switch 1350 (or 1450 of FIG. 14) is operated/configured in a closed state, the state of the associated second plurality of switches 1357 (e.g., SM2-S1, SM2-S2, SM2-S3) (or alternative second plurality of switches 1457 (e.g., SM_Alt-S1, SM_Alt-S2, SM_Alt-S3, SM_Alt-S4)) is open. In other words, closing the termination switch 1350, 1450 excludes the closure of any of the associated second plurality of switches 1357, 1457 (i.e., SM2-S4 and SM_Alt-S5 may not be in a closed state when any of SM2-S1, SM2-S2, SM2-S3, SM2-S4 and SM_Alt-S1, SM_Alt-S2, SM_Alt-S3, SM_Alt-S4, respectively, are in a closed state).

The apparatus 1400 (as illustrated in any one of FIGS. 13, 14, 15A, 15B, 16A, 16B, and 16C) may facilitate a use of a configurable low noise amplifier input matching network, which can be switched between at least two matching network configurations to impedance match the various output impedances of the plurality of bandpass filters (e.g., 1304, where each bandpass filter has a center frequency and passband that is different from the other bandpass filters) to the input impedance of the low noise amplifier input node (e.g., 1330 of FIG. 14) of the single low noise amplifier (e.g., 1310 of FIG. 14) via the at least two configurations of matching networks.

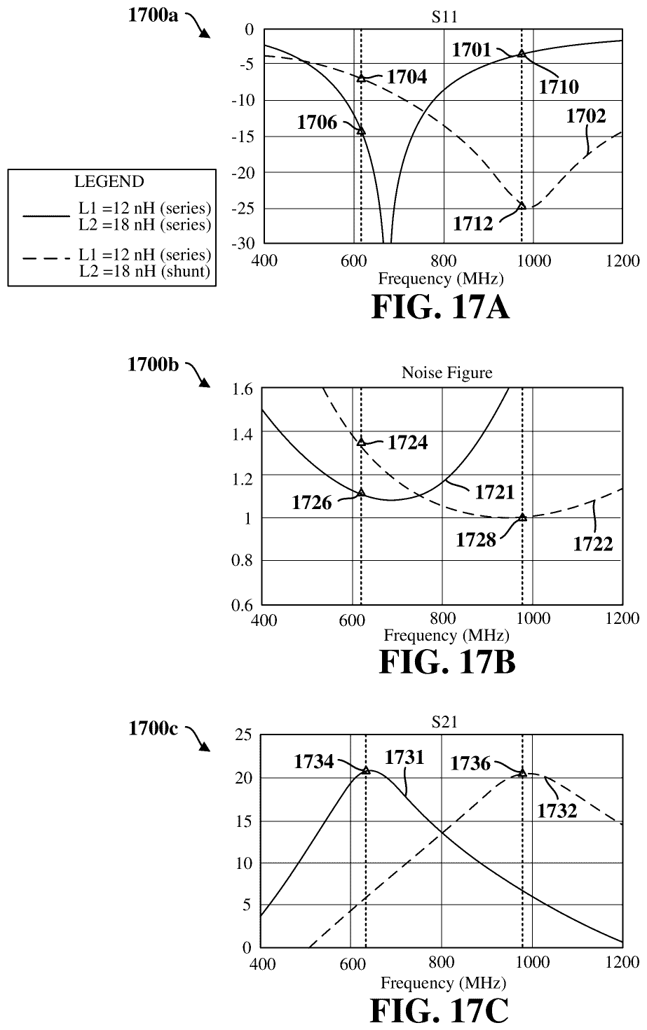

FIGS. 17A, 17B, and 17C are graphs of S11 1700, noise FIGS. 1701, and S21 1702 for the second matching network 1632 configuration/instantiation (e.g., series-series) of FIG. 16B and the third matching network 1633 configuration/instantiation (e.g., shunt-series) of FIG. 16C according to some aspects of the disclosure. As depicted in FIG. 17A, the shunt-series configuration (i.e., the third matching network 1633 configuration of FIG. 16C) offers good matching (where the lower the value of S11, the better the matching) for the higher frequency area (see second trace 1702), and the series-series configuration (i.e., the second matching network 1632 configuration of FIG. 16B) offers good matching for the lower frequency area (see first trace 1701). Compare S11 of second trace 1702 at first marker 1704 of −7.05 dB at 617 MHz to first trace 1701 at second marker 1706 of −14 dB at 617 MHz. Compare S11 of second trace 1702 at third marker 1712 of −25 dB at 960 MHz to first trace 1701 at fourth marker 1710 of −3.3 dB at 960 MHz. It is also noted, though not illustrated in FIG. 17A, that increasing series inductance in the series-series configuration facilitates lower frequency tuning for the matching network.

As depicted in FIG. 17B, the shunt-series configuration (i.e., the third matching network 1633 configuration of FIG. 16C) offers good noise figure (where the lower the value of noise figure, the better the sensitivity of the receiver) for the higher frequency area (see trace 1722) and the series-series configuration (i.e., the second matching network 1632 configuration of FIG. 16B) offers good noise figure for the lower frequency area (see trace 1721). Compare noise figure of second trace 1722 at first marker 1724 of 1.37 dB at 617 MHz to first trace 1721 at second marker 1726 of 1.08 dB at 617 MHz. See noise figure of second trace 1702 at third marker 1728 of 1.0 dB at 960 MHz.

As depicted in FIG. 17C, the gain of the low noise amplifier with a matching network in the shunt-series configuration (i.e., the third matching network 1633 configuration of FIG. 16C) at the higher frequency area (see trace 1732) is substantially similar to the gain of the low noise amplifier with a matching network in the series-series configuration (i.e., the second matching network 1632 configuration of FIG. 16B) at the lower frequency area (see trace 1731). For example, the 21.0 dB peak gain at second marker 1734 is substantially similar to 20.9 dB peak gain at first marker 1736. See gain (S21) of second trace 1732 at first marker 1736 of 21.0 dB at 960 MHz. See gain (S21) of first trace 1731 at second marker 1734 of 21.0 dB at 617 MHz. It is noted that the gain (S21) does not degrade in contrast to the degradation experienced in connection with the Cgs tuning provided in the example of FIG. 9 and illustrated in the graph of FIG. 10C.

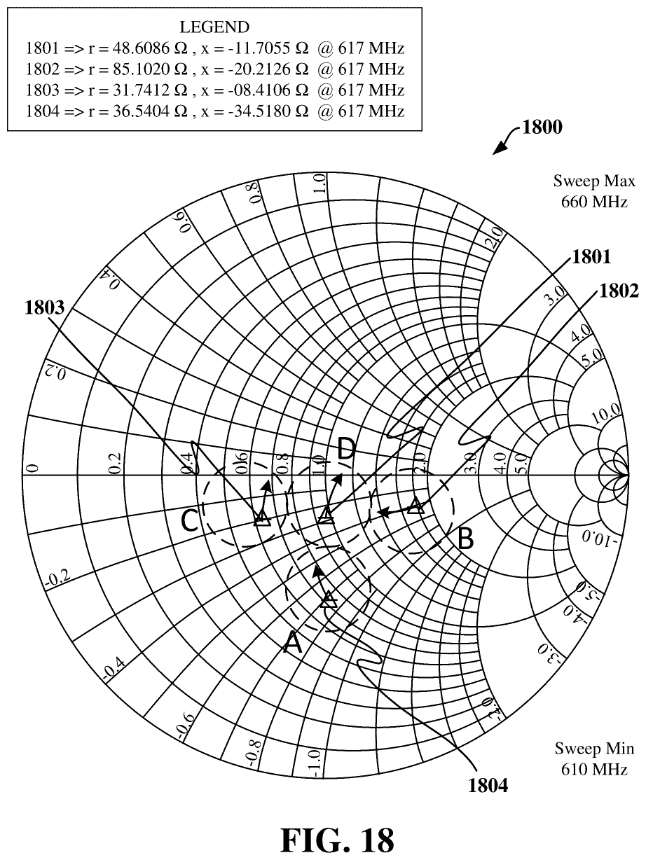

FIG. 18 is a Smith chart depicting the impedance looking into an output of a given configuration of a matching network as the frequency is swept from 610 MHz to 660 MHz, according to some aspects of the disclosure. See Tables 2 and 3 for additional details.

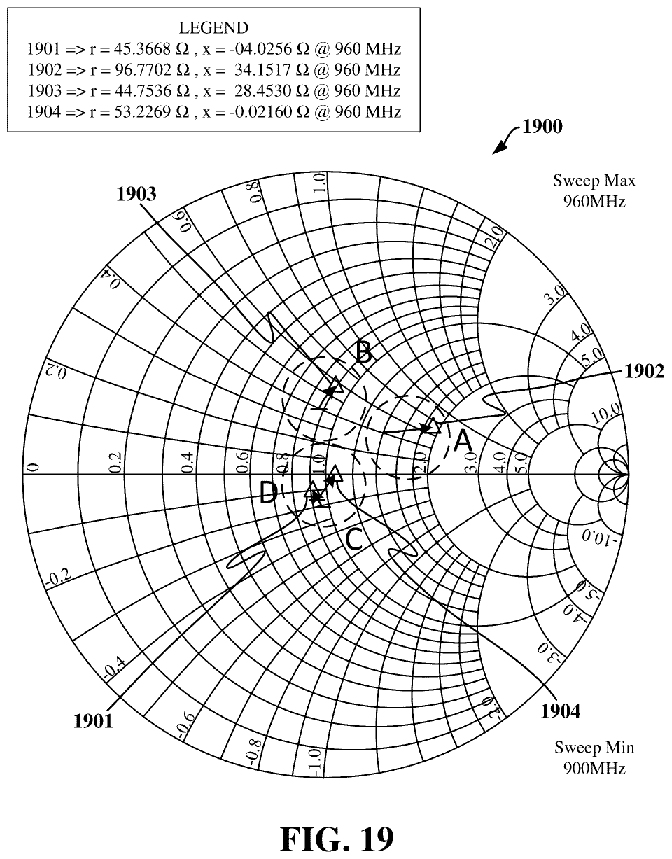

FIG. 19 is a Smith chart depicting the impedance looking into an output of a given configuration of a matching network as the frequency is swept from 900 MHz to 960 MHz, according to some aspects of the disclosure. See Tables 2 and 3 for additional details.

The filters used in the examples described herein may be acoustic filters (e.g., SAW filters). Filters may be above or below 50 Ohms in impedance. Typically, the desired load impedance is around 50 Ohms. Any load impedance is within the scope of the disclosure. Configuring the low noise amplifier input matching network may provide overall module performance improvement and cost savings. Table 2 identifies the configurations (other than the swept frequency ranges) utilized in generating the Smith charts of FIGS. 18 and 19.

TABLE 2

| Configuration | Style | Parameters | Compare to |
|---|---|---|---|
| A | Series-only | L1 = 22 nH | Compromise shown |
| | | | in FIGs. 6A and 6B |
| B | Shunt-series | L1 = 18 nH, | Compromise shown |
| | | L2 = 20 nH | in FIGs. 8A, 8B |
| C | Cgs tuning | L1 = 16 nH, | Compromise shown |
| | | C_{gs} = 2 pF | in FIGs. 10A, 10B, |
| | | | 10C |
| D | Configurable low | L1 = 12 nH | See FIGs. 17A, |
| | noise amplifier | and L2 = 18 | 17B, and 17C |
| | input matching | nH in series | |
| | network in | | |
| | series-series | | |
| | configuration of | | |
| | FIG. 16B | | |

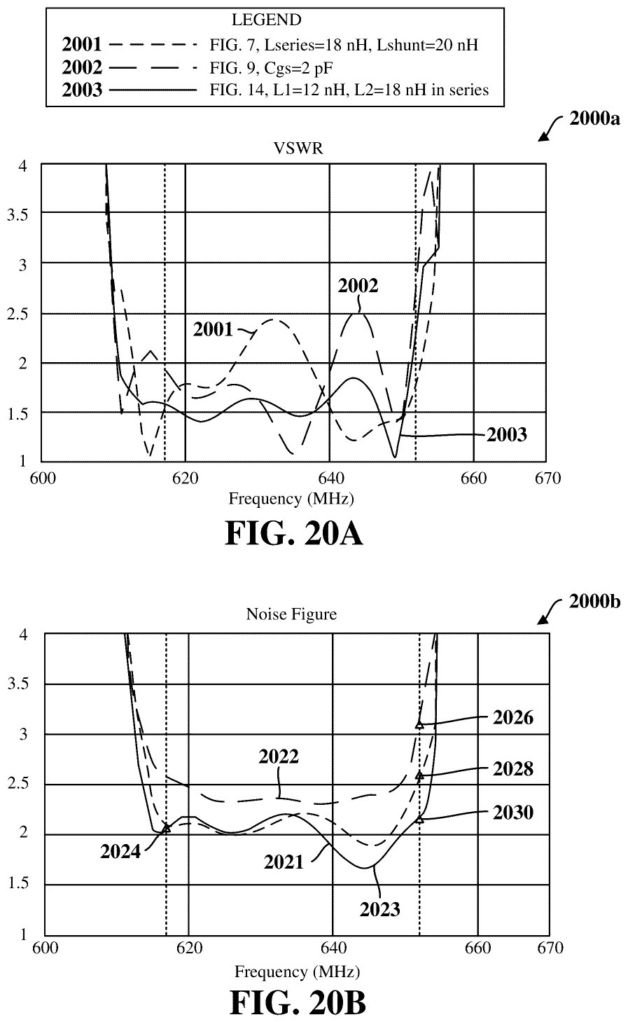

FIGS. 20A and 20B are graphs of voltage standing wave ratio (VSWR) 2000a and noise FIG. 2000b simulations utilizing an n71 filter over a swept frequency ranging from 600 MHz to 670 MHz, according to some aspects of the disclosure. Table 3 identifies the configurations used in generating the VSWR and noise figure graphs of FIGS. 20A and 20B, respectively. By comparing the three configurations represented by the graphs of FIGS. 20A and 20B, a conclusion can be drawn regarding the overall best antenna matching (VSWR better than 2:1) and flattest noise figure. By comparing the graphs, the best antenna matching (VSWR better than 2:1) and flattest noise figure may be achieved with configuration D (the configurable low noise amplifier input matching network as shown and described herein).

TABLE 3

| Configuration | Style | Parameters | Compare to |
|---|---|---|---|
| B | Shunt-series | L1 = 18 nH, | Compromise shown |
| | | L2 = 20 nH | in FIGs. 8A, 8B |
| C | Cgs tuning | L1 = 16 nH, | Compromise shown |
| | | C_{gs} = 2 pF | in FIGs. 10A, 10B, |
| | | | 10C |
| D | Configurable low | L1 = 12 nH | See FIGs. 17A, |
| | noise amplifier | and L2 = 18 | 17B, and 17C |
| | input matching | nH in series | |
| | network in | | |
| | series-series | | |
| | configuration of | | |
| | FIG. 16B | | |

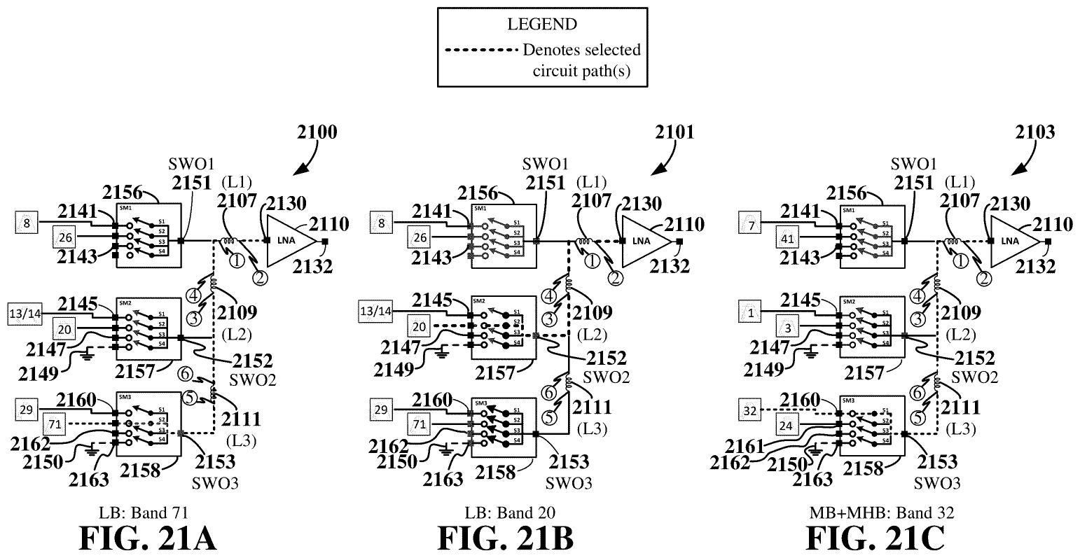

FIGS. 21A, 21B, and 21C are simplified schematic drawings of three instantiations (different configurations of the same apparatus based on different switches being closed/opened) of a configurable low noise amplifier input matching network according to some aspects of the disclosure. The examples of FIGS. 21A, 21B, and 21C serve as an example of how the aspects of a first plurality of switches 2156 and second plurality of switches 2157 (e.g., similar to as 1356, 1357 of FIGS. 13, 14, 15A, 15B, 16A, 16B, 16C) can be extended in frequency to serve a wider bandwidth filter network coupled to a low noise amplifier 2130 (e.g., similar to 1310 of FIGS. 13, 14, 15A, 15B, 16A, 16B, 16C). The dashed lines of FIGS. 21A, 21B, and 21C identify the circuit path configured to carry a signal according to some aspects of the disclosure.

Specifically, the matching network may be split into more than two sections (e.g., more than a first plurality of switches 1356 and a second plurality of switches 1357). In the example of FIGS. 21A, 21B, and 21C, the matching network is split into the first plurality of switches 2156, a second plurality of switches 2157, and at least one additional plurality of switches 2158. Although there may be a penalty to the extension in the form of an extra output bump, the inductor area need not necessarily increase as the coils of the inductors may be realized with a single tapped inductor. Accordingly, the configurable low noise amplifier input matching network exemplified, for example, in FIGS. 13, 14, 16A, 16B, and 16C may be extended from the low bands, such as bands n71 and n20, to the mid-band and mid-high-band bands (e.g., bands from 1.5 GHz to 2.69 GHz) and/or to any application requiring wideband operation. An example of the mid-band and mid-high-band bands may be found in LTE band 32. LTE band 32 is utilized in an FDD configuration. The bandwidth of LTE band 32 ranges from 1452 MHz to 1496 MHz.

In general, the configurable low noise amplifier input matching network (e.g., an apparatus) of FIGS. 21A, 21B, and 21C may include: a first plurality of switches (e.g., the first plurality of switches 2156 with the plurality of switches SM1-S1, SM1-S2, SM1-S3, SM1-S4) having a respective first plurality of input nodes (e.g., 2141, 2142, 2143, 2144) and a first common output node (e.g., SWO1 2151), a second plurality of switches (e.g., second plurality of switches 2157 with switches SM2-S1, SM2-S2, SM2-S3, SM2-S4) having a respective second plurality of input nodes (e.g., 2145, 2146, 2147) and a second common output node (e.g., SWO2 2152), a termination switch (e.g., switch SM2-S5), different from any of the first plurality of switches (SM1-S1, SM1-S2, SM1-S3, SM1-S4) and the second plurality of switches (SM1-S1, SM1-S2, SM1-S3, SM1-S4), coupled to the second common output node SWO2 2152 and selectively coupled to a ground termination 2149 (e.g., where the selective coupling may be by operation of the termination switch (e.g., SM2-S5), by configuring the termination switch to enter a closed state, by closing the termination switch, or by any other method of utilizing the termination switch to couple the second common output node SWO2 2152 to a ground, such as the ground termination 2149).

The configurable low noise amplifier input matching network (e.g., the apparatus) of FIGS. 21A, 21B, and 21C may further include at least one additional plurality of switches (e.g., included with the at least one additional plurality of switches 2158) having a respective at least one additional plurality of input nodes (e.g., 2160, 2161, 2162, 2163) and an at least one additional common output node (e.g., SWO3 2153), at least one additional termination switch, different from any of the first plurality of switches, the second plurality of switches, the termination switch, and the at least one additional plurality of switches, coupled to the at least one additional common output node (e.g., SWO3 2153) and selectively coupled to an additional ground termination 2150 (or the ground termination 2149).

The configurable low noise amplifier input matching network (e.g., the apparatus) of FIGS. 21A, 21B, and 21C may further include a low noise amplifier (e.g., 2110) having a low noise amplifier input node (e.g., 2130) and a low noise amplifier output node (e.g., 2132), a first matching component (e.g., L1 2107) coupled at a first node 0001 to the first common output node (e.g., 2151 SWO1) and at a second node 0002 to the low noise amplifier input node (e.g., 2130), a second matching component (e.g., L2 2109) coupled at a third node 0003 to the second common output node (e.g., SWO2 2152) and at a fourth node 0004 to the first common output node (e.g., SWO1 2151) and the first node 0001, and at least one additional matching component (e.g., L3 2111) coupled at a fifth node (identified by the number 5 in a circle) to the at least one additional common output node (e.g., SWO3 2153) and at a sixth node (identified by the number 6 in a circle) to the second common output node (e.g., SWO2 2152).

As illustrated in FIG. 21A, the configurable low noise amplifier input matching network (e.g., the apparatus) configured to operate in a low band, such as band n71, may close switch SM3-S2 (coupled to an n71 filter) and leave all other switches in the apparatus open. In such a series-series-series configuration, the matching network is the series combination of the inductors L1 2107, L2 2109, and L3 2111.

As illustrated in FIG. 21B, the configurable low noise amplifier input matching network (e.g., the apparatus) configured to operate in the low band but at a higher frequency than the n71 frequency band, such as band n20, may close switch SM2-S2 (coupled to an n20 filter), and leave all other switches in the apparatus open. In such a series-series configuration, the matching network is the series combination of the inductors L1 2107 and L2 2109.

As illustrated in FIG. 21C, the configurable low noise amplifier input matching network (e.g., the apparatus) configured to operate in a mid-band or mid-high band (at channel frequencies greater than the examples of bands n71 to n8) (ranging from 663-915 MHz), such as LTE band 32 (ranging from 1450-1496 MHz), may close switch SM3-S1 (coupled to an LTE band 32 filter), and leave all other switches in the apparatus open. In such a series-series-series configuration, the matching network is the series combination of the inductors L1 2107, L2 2109, and L3 2111.

The configurations (e.g., topologies) of circuits provided in the examples of FIGS. 13, 14, 15A, 15B, 16A, 16B, and 16C described herein offer at least two input matching network configurations (topologies). Utilizing FIGS. 16A, 16B, and 16C as illustrative and non-limiting examples, three matching network configurations may be obtained. A first matching network 1631 configuration is exemplified in FIG. 16A and includes the first matching component 1307 in series and the second matching component 1309 floating. A second matching network 1632 configuration is exemplified in FIG. 16B and includes the first matching component 1307 in series with the second matching component 1309. A third matching network 1633 configuration is exemplified by in FIG. 16C and includes the first matching component 1307 (e.g., L1) in series and the second matching component 1309 in shunt (i.e., connected to ground via SPST SM2-S4).

Additionally, the configurations (e.g., topologies) of circuits provided in the examples of FIGS. 21A, 21B, 21C described herein offer at least four input matching network configurations (topologies). Utilizing FIGS. 21A and 21B as illustrative and non-limiting examples, a first configuration (not shown but similar to the first configuration 1600 of FIG. 16A) includes the first matching component 1307 (e.g., L1) in series and the second matching component 1309 (or the third matching component L3 2111) in shunt (i.e., connected to ground via SPST switch SM2-S5 or SM3-S5); a second configuration (not shown but similar to the second configuration 1601 of FIG. 16B) includes the first matching component L1 2107 in series and the second matching component L2 2109 and the third matching component L3 2111 floating; a third configuration 2100 (exemplified by in FIG. 21A) includes the first matching component L1 2107 in series with the second matching component L2 2109, and also in series with the third matching component L3 2111; and a fourth configuration 2101 (exemplified by in FIG. 21B) includes the first matching component L1 2107 in series with the second matching component L2 2109 and the third matching component L3 2111 floating. All configurations described herein may be examples of configurable low noise amplifier input matching networks.

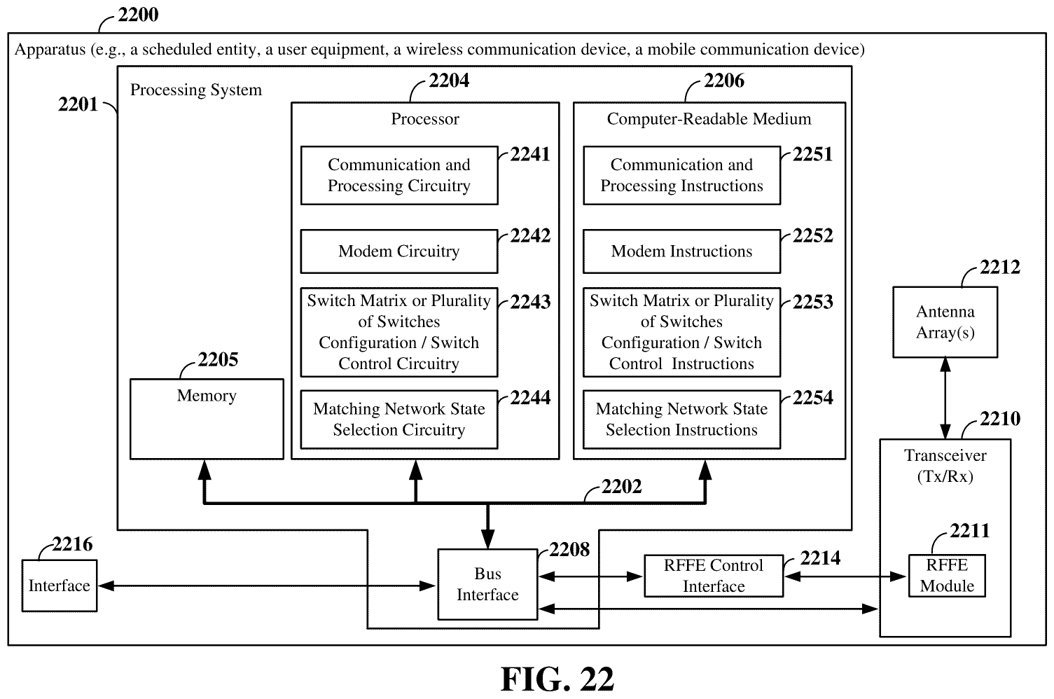

FIG. 22 is a block diagram illustrating an example of a hardware implementation of an apparatus 2200 (e.g., a scheduled entity, a user equipment, a wireless communication device, a mobile communication device) employing one or more processing systems (generally represented by processing system 2201) according to some aspects of the disclosure. The apparatus 2200 may be similar to, for example, any of the scheduled entities, user equipment, wireless communication devices, and mobile communication devices as shown and described in connection with FIG. 1.

In accordance with various aspects of the disclosure, an element, any portion of an element, or any combination of elements may be implemented with a processing system 2201 that includes one or more processors, generally represented by processor 2204. Examples of processor 2204 include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. In various examples, the apparatus 2200 may be configured to perform any one or more of the functions described herein. That is, the one or more processors (generally represented by processor 2204), as utilized in the apparatus 2200, may be configured to, individually or collectively, implement any one or more of the methods or processes described and illustrated, for example, in or in connection with FIGS. 2, 4, 5, 7, 9, 11-14, 20 and 21.

In this example, the processing system 2201 may be implemented with a bus architecture, represented generally by the bus 2202. The bus 2202 may include any number of interconnecting buses and bridges depending on the specific application of the processing system 2201 and the overall design constraints. The bus 2202 communicatively couples together various circuits, including one or more processors (represented generally by the processor 2204), one or more memories (represented generally by a memory 2205), and one or more computer-readable media (represented generally by the computer-readable medium 2206). The bus 2202 may also link various other circuits such as timing sources, peripherals, voltage regulators, and power management circuits, which are well known to persons having ordinary skill in the art and, therefore, will not be described any further.

A bus interface 2208 provides an interface between the bus 2202 and a transceiver 2210. The transceiver may be similar to the transceiver 2210, as shown and described in connection with FIG. 2. The transceiver 2210 may be, for example, a wireless transceiver. The transceiver 2210 may be operational with multiple RATs (e.g., LTE, 5G NR, IEEE 802.11 (WiFi®), etc.). The transceiver 2210 may provide respective means for communicating with various other apparatus, scheduling entities, UEs, and core networks over a transmission medium (e.g., air interface).

In some examples, the transceiver 2210 or the RFFE module 2211 may include a first bandpass filter having a first center frequency coupled to a first input node of a first plurality of switches, a second bandpass filter having a second center frequency, lower than the first center frequency, coupled to a second input node of the first plurality of switches, and a third bandpass filter having a third center frequency, lower than the second center frequency, coupled to a given input node of the second plurality of input nodes, where, based on respective states of the first plurality of switches, the second plurality of switches, and the termination switch, the apparatus 2200 is respectively configured to: match a first output impedance of the first bandpass filter as seen at the first common output node to an input impedance of the low noise amplifier via a first series inductance matching network, match a second output impedance of the second bandpass filter as seen at the first common output node to the input impedance of the low noise amplifier via a shunt inductance-series inductance matching network, and match a third output impedance of the third bandpass filter as seen at the second common output node to the input impedance of the low noise amplifier via a second series inductance matching network, the second series inductance of the second series inductance matching network comprising a first sum of inductances of the first matching component and the second matching component.

In some examples, the transceiver 2210 or the RFFE module 2211 may include a first bandpass filter having a first center frequency coupled to a first input node of the first plurality of switches, a second bandpass filter having a second center frequency, lower than the first center frequency, coupled to a second input node of the second plurality of switches, and a third bandpass filter having a third center frequency, lower than the second center frequency, coupled to a third input node of the at least one additional plurality of switches, wherein, based on respective states of the first plurality of switches, the second plurality of switches, the termination switch, the at least one additional plurality of switches, and the at least one additional termination switch, the apparatus 2200 is respectively configured to: match a first output impedance of the first bandpass filter as seen at the first common output node to an input impedance of the low noise amplifier via a first series inductance matching network, a first value of the first series inductance matching network comprising the inductance of the first matching component, match a second output impedance of the second bandpass filter as seen at the second common output node to the input impedance of the low noise amplifier via a second series inductance matching network, a second value of the second series inductance matching network comprising a first sum of inductances of the first matching component and the second matching component, and match a third output impedance of the third bandpass filter as seen at the at least one additional common output node to the input impedance of the low noise amplifier via a third series inductance matching network, a third value of the third series inductance matching network comprising a second sum of inductances of the first matching component, the second matching component, and the at least one additional matching component.

According to some examples, the first plurality of switches may be configured as a first preselector switch matrix, the second plurality of switches and the termination switch may be configured as a second preselector switch matrix, and, if utilized, the at least one additional plurality of switches and the at least one additional termination switch may be configured as a third preselector switch matrix. In some examples, the first plurality of switches may be configured as a first multiplexer, the second plurality of switches and the termination switch may be configured as a second multiplexer, and, if utilized, the at least one additional plurality of switches and the at least one additional termination switch may be configured as a third multiplexer.

The transceiver 2210 may be coupled to one or more antenna array(s) 2212. The antenna array(s) 2212 may be similar to the antenna 236, as shown and described in connection with FIG. 2. The bus interface 2208 may provide an interface between the bus 2202 and a user interface 2216 (e.g., keypad, display, touch screen, speaker, microphone, control features, vibration circuit/device, etc.). The user interface 2216 is optional and may be omitted in some examples. The bus interface 2208 may also provide an interface between the bus 2202 and a radio frequency (RF) front-end (RFFE) control interface 2214. The RFFE control interface 2224 may be similar to the RFFE control interface 414, as shown and described in connection with FIG. 4. The RFFE control interface may control an RF front-end of the transceiver 2210. According to some aspects, the RFFE control interface may be integrated with the RF front-end of the transceiver 2210. More specifically, according to some aspects, the RFFE control interface may be fabricated or included with an integrated circuit, such as the integrated circuit 418, as shown and described in connection with FIG. 4. The integrated circuit 418 may be a component of an RFFE module 2211, similar to the RFFE module 400 as shown and described in connection with FIG. 4, of the transceiver 2210.

One or more processors, represented individually and collectively by processor 2204, may be responsible for managing the bus 2202 and general processing, including the execution of software stored on the computer-readable medium 2206. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise. The software may reside on the computer-readable medium 2206. The software, when executed by the processor 2204, causes the processing system 2201 to perform the various processes and functions described herein for any particular apparatus.

The computer-readable medium 2206 may be a non-transitory computer-readable medium and may be referred to as a computer-readable storage medium or a non-transitory computer-readable medium. The non-transitory computer-readable medium may store computer-executable code (e.g., processor-executable code). The computer executable code may include code for causing a computer (e.g., a processor) to implement one or more of the functions described herein. A non-transitory computer-readable medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a card, a stick, or a key drive), a random access memory (RAM), a read only memory (ROM), a programmable ROM (PROM), an erasable PROM (EPROM), an electrically erasable PROM (EEPROM), a register, a removable disk, and any other suitable medium for storing software and/or instructions that may be accessed and read by a computer. The computer-readable medium 2206 may reside in the processing system 2201, external to the processing system 2201, or distributed across multiple entities, including the processing system 2201. The computer-readable medium 2206 may be embodied in a computer program product or article of manufacture. By way of example, a computer program product or article of manufacture may include a computer-readable medium in packaging materials. In some examples, the computer-readable medium 2206 may be part of the memory 2205. Persons having ordinary skill in the art will recognize how best to implement the described functionality presented throughout this disclosure depending on the particular application and the overall design constraints imposed on the overall system. The computer-readable medium 2206 and/or the memory 2205 may also be used for storing data that is manipulated by the processor 2204 when executing software.

In some aspects of the disclosure, the processor 2204 may include communication and processing circuitry 2241 configured for various functions, including, for example, communicating with a network entity (e.g., a scheduling entity, a base station, an aggregated or disaggregated base station, an eNB, a gNB, a TRP), another apparatus, and/or a core network. In some examples, the communication and processing circuitry 2241 may include one or more hardware components that provide the physical structure that performs processes related to wireless communication (e.g., signal reception and/or signal transmission) and signal processing (e.g., processing a received signal and/or processing a signal for transmission). In some examples, the communication and processing circuitry may be configured to present one of a plurality of matching network configurations to the low noise amplifier input node based on respective states of the first plurality of switches, the second plurality of switches, and the termination switch. According to some aspects, the plurality of matching network configurations may include a first series matching network, a shunt-series matching network, and a second series matching network configured differently from the first series matching network. According to some aspects, the first series matching network may include the first matching component coupled at the first node to the first common output node and at the second node to the low noise amplifier input node, the shunt-series matching network may include: the first matching component coupled at the first node to the first common output node and at the second node to the low noise amplifier input node, and the second matching component may be coupled: at the fourth node to the first node of the first matching component and the first common output node, and at the third node to a short circuit to a ground via the termination switch, and the second series matching network may include: the first matching component coupled at the second node to the low noise amplifier input node and at the first node to the fourth node of the second matching component, and the second matching component coupled at the fourth node to the first node of the first matching component and at the third node to the second common output node.

According to some examples, the communication and processing circuitry 2241 may be configured to present one of a plurality of matching network configurations to the low noise amplifier input node based on respective states of the first plurality of switches, the second plurality of switches, the termination switch, the at least one additional plurality of switches, and the at least one additional termination switch. The plurality of matching network configurations may include a first series matching network, a second series matching network configured differently from the first series matching network, and a third series matching network configured differently from the first series matching network and the second series matching network, where a first value of impedance of the first series matching network may be less than a second value of impedance of the second series matching network, and the second value of impedance of the second series matching network may be less than a third value of impedance of the third series matching network.

The communication and processing circuitry 2241 may further be configured to execute communication and processing instructions 2251 (e.g., software) stored on the computer-readable medium 2206 to implement one or more functions described herein.

In some aspects of the disclosure, the processor 2204 may include modem circuitry 2242 configured for various functions, including, for example, receiving and providing user data and control signaling from and to the processor 2204 of the processing system 2201 and modulating and demodulating the user data and control signaling. The modem circuitry 2242 may be similar to the circuitry of the modem 238, as shown and described in connection with FIG. 2. The modem circuitry 2242 may be configured to execute modem instructions 2252 (e.g., software) stored on the computer-readable medium 2206 to implement the functions described herein.

In some aspects of the disclosure, the processor 2204 may include switch matrix or plurality of switches configuration/control circuitry (hereinafter control circuitry 2243 or a control circuit) configured for various functions, including, for example, configuring a first plurality of switches having a respective first plurality of input nodes and a first common output node, configuring a second plurality of switches having a respective second plurality of input nodes and a second common output node, and in some examples configuring at least one additional plurality of switches having a respective at least one additional plurality of input nodes and at least one additional common output node. The control circuitry 2243 may also be configured for other various functions, including, for example, configuring a termination switch (and in some examples, at least one additional termination switch), different from any of the first plurality of switches and the second plurality of switches (and in some examples, different from the at least one additional plurality of switches). The termination switch and/or the at least one additional termination switch may be coupled to the second common output node (and, in some examples, to the third common output node, respectively) and selectively coupled to a ground termination.

According to some aspects, the termination switch may be configured to present at least one of an open circuit to the second common output node, or a short circuit to a ground to the second common output node. In some examples, the at least one additional termination switch may be configured to present at least one of: an additional open circuit to the at least one additional common output node, or an additional short circuit to the ground to the at least one additional common output node.

According to some examples, the control circuitry 2243 (e.g., the control circuit) may further be configured to output a control signal to configure a respective state of each of the first plurality of switches, the second plurality of switches, and the termination switch. In some additional examples, the control circuitry 2243 may further be configured to output a control signal to configure a respective state of each of the at least one additional plurality of switches and the at least one additional termination switch.

The control circuitry 2243 may further be configured to execute switch matrix or plurality of switches configuration/switch control instructions 2253 (e.g., software) stored on the computer-readable medium 2206 to implement one or more functions described herein.

In some aspects of the disclosure, the processor 2204 may include matching network state selection circuitry 2244 configured for various functions, including, for example, configuring or selecting a state of a first matching component coupled at a first node to the first common output node and at a second node to a low noise amplifier input node, configuring or selecting a state of a second matching component coupled at a third node to the second common output node and at a fourth node to the first common output node and the first node, and in some examples, configuring or selecting a state of at least one additional matching component coupled at a fifth node to the at least one additional common output node and at a sixth node to the second common output node. The low noise amplifier may be similar to any of the low noise amplifiers 210, 410, 510, 710, 910, 1114, 1116, 1210, 1310 and 2110, as shown and described in FIGS. 2, 4, 5, 7, 9, 11, 12, 13-16, and 21, respectively.

In some aspects of the disclosure, the matching network state selection circuitry 2244 may be configured for other various functions, including, for example: configuring a first plurality of switches coupled between respective ones of a first plurality of input nodes and a first common output node to have either: a first state in which a first switch between a first input node of the first plurality of input nodes and the first common output node is closed and remaining switches of the first plurality of switches are open, or a second state in which each of the first plurality of switches are open; configuring a second plurality of switches coupled between respecting ones of a second plurality of input nodes and a second common output node to have either: a third state in which a given switch between a given input node of the second plurality of input nodes and the second common output node is closed and remaining switches of the second plurality of switches are open, or a fourth state in which each of the second plurality of switches are open; and configuring a termination switch, coupled between the second common output node and a termination to either: a fifth state in which the termination switch is closed, or a sixth state in which the termination switch is open, where: the first state, the fourth state, and the sixth state exist concurrently and exclusive of the second state, the third state, and the fifth state; the second state, the third state, and the sixth state exist concurrently and exclusive of the first state, the fourth state, and the fifth state; or the first state, the fourth state, and the fifth state exist concurrently and exclusive of the second state, the third state, and the sixth state.

According to some examples, the first matching component may be a series inductor coupled between the low noise amplifier input node and the one of the first plurality of input nodes, and the second matching component may be terminated with an open circuit at the third node. In some examples, the at least one additional matching component may be terminated with a second open circuit at the fifth node. According to some examples, the first matching component may be a series inductor coupled at the second node to the low noise amplifier input node and at the first node to the one of the first plurality of input nodes, and the second matching component may be a shunt inductor coupled at the fourth node to the first node of the first matching component and at the third node to a short circuit to a ground via the termination switch. In some examples, the at least one additional matching component may be terminated with an open circuit at the fifth node.

According to some examples, the first matching component may be a first series inductor coupled at the second node to the low noise amplifier input node and at the first node to the fourth node of the second matching component, and the second matching component may be a second series inductor coupled at the fourth node to the first node of the first matching component and at the third node to the one of the second plurality of input nodes. In some examples, at least one additional matching component may be a third series inductor coupled at the sixth node to the third node of the second matching component and at the fifth node to the one of the at least one additional plurality of input nodes via one of the at least one additional plurality of switches.

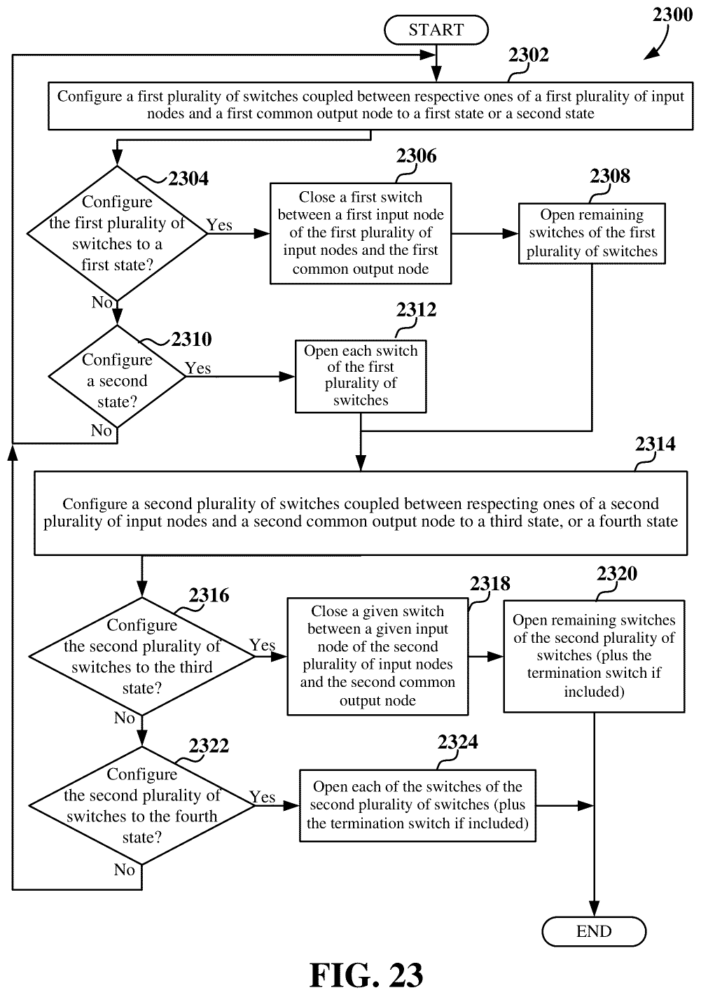

FIG. 23 is a flow chart illustrating an example process 2300 (e.g., a method) at an apparatus (e.g., a scheduled entity, a user equipment, a wireless communications device, a mobile communication device) according to some aspects of the disclosure. As described below, some or all illustrated features may be omitted in a particular implementation within the scope of the present disclosure, and some illustrated features may not be required for the implementation of all examples. In some examples, the process 2300 may be carried out by the apparatus 2200, as shown and described in connection with FIG. 22. The apparatus 2200 may be similar to, for example, any of the scheduled entities, user equipment, wireless communications devices, and/or mobile communication devices as shown and described in connection with FIG. 1. In some examples, the process 2300 may be carried out by any suitable apparatus or means for carrying out the functions or algorithm described below.

At block 2302, the apparatus may configure a first plurality of switches coupled between respective ones of a first plurality of input nodes and a first common output node to at least one of a first state or a second state. For example, the control circuitry 2243, as shown and described in connection with FIG. 22, may provide a means for configuring a first plurality of switches coupled between respective ones of a first plurality of input nodes and a first common output node to at least one of a first state or a second state.

At block 2304, the apparatus may determine whether to configure the first plurality of switches to a first state. For example, the communication and processing circuitry 2241, as shown and described in connection with FIG. 22, may provide a means for determining whether to configure the first plurality of switches to a first state. In response to determining to configure the first plurality of switches to the first state, the process 2300 may continue to block 2306.

At block 2306, the apparatus may close a first switch between a first input node of the first plurality of input nodes and the first common output node. At block 2308, the apparatus may open the remaining switches of the first plurality of switches. For example, the control circuitry 2243, as shown and described in connection with FIG. 22, may provide a means for opening the remaining switches of the first plurality of switches. Thereafter, the apparatus may proceed to block 2314.

Returning to block 2304, in response to determining not to configure the first plurality of switches to the first state, the process 2300 may continue to block 2310. For example, the communication and processing circuitry 2241, as shown and described in connection with FIG. 22, may provide a means for determining not to configure the first plurality of switches to the first state.

At block 2310, the apparatus may determine whether to configure the first plurality of switches to the second state. For example, the communication and processing circuitry 2241, as shown and described in connection with FIG. 22, may provide a means for determining whether to configure the first plurality of switches to the second state. In response to determining to configure the first plurality of switches to the second state, the process 2300 may continue to block 2312.

At block 2312, the apparatus may open each of the first plurality of switches. Thereafter, the process 2300 may continue to block 2314. For example, the control circuitry 2243, as shown and described in connection with FIG. 22, may provide a means for opening each of the first plurality of switches.

Returning to block 2310, in response to determining not to configure the first plurality of switches to the second state, the process 2300 may return to block 2302. For example, the communication and processing circuitry 2241, as shown and described in connection with FIG. 22, may provide a means for determining not to configure the first plurality of switches to the second state and a means for returning the process to block 2302.

Turning now to block 2314, the apparatus may configure a second plurality of switches coupled between respecting ones of a second plurality of input nodes and a second common output node plus a termination switch coupled between a ground and the second common output node to have at least one of: a third state, a fourth state, or a fifth state. For example, the control circuitry 2243, as shown and described in connection with FIG. 22, may provide a means for configuring a second plurality of switches coupled between respecting ones of a second plurality of input nodes and a second common output node plus a termination switch coupled between a ground and the second common output node to have at least one of: a third state, a fourth state, or a fifth state.

At block 2316, the apparatus may determine whether to configure the second plurality of switches to the third state. For example, the communication and processing circuitry 2241, as shown and described in connection with FIG. 22, may provide a means for determining whether to configure the second plurality of switches to the third state. In response to determining to configure the second plurality of switches to the third state, the process 2300 may continue to block 2318.

At block 2318, the apparatus may close a given switch, of the second plurality of switches, between a given input node of the second plurality of input nodes and the second common output node. For example, the control circuitry 2243, as shown and described in connection with FIG. 22, may provide a means for closing a given switch, of the second plurality of switches, between the given input node of the second plurality of input nodes and the second common output node.

At block 2320, the apparatus may open the remaining switches of the second plurality of switches and, in addition, may open the termination switch if the termination switch is present. Thereafter, the process 2300 may end. For example, the control circuitry 2243, as shown and described in connection with FIG. 22, may provide a means for opening the remaining switches of the second plurality of switches and, in addition, a means for opening the termination switch if the termination switch is present.

Returning to block 2316, in response to determining not to configure the second plurality of switches to the third state, the process 2300 may continue to block 2322. For example, the communication and processing circuitry 2241, as shown and described in connection with FIG. 22, may provide a means for determining not to configure the second plurality of switches to the third state.

At block 2322, the apparatus may determine whether to configure the second plurality of switches to the fourth state. For example, the communication and processing circuitry 2241, as shown and described in connection with FIG. 22, may provide a means for determining whether to configure the second plurality of switches to the fourth state. In response to determining to configure the second plurality of switches to the fourth state, the process 2300 may continue to block 2324.

At block 2324, the apparatus may open each of the switches of the second plurality of switches and, in addition, may open the termination switch if the termination switch is present. For example, the control circuitry 2243, as shown and described in connection with FIG. 22, may provide a means for opening each of the switches of the second plurality of switches and, in addition, may provide a means for opening the termination switch if the termination switch is present. Thereafter, the process 2300 may end.

Returning to block 2316, in response to determining not to configure the second plurality of switches to the fourth state, the process 2300 may continue to block 2326. For example, the communication and processing circuitry 2241, as shown and described in connection with FIG. 22, may provide a means for determining not to configure the second plurality of switches to the fourth state.

According to some aspects, the first state, the fourth state, and the sixth state exist concurrently and exclusive of the second state, the third state, and the fifth state (i.e., the apparatus may be in the first state, the fourth state, and the sixth state simultaneously; however, if in the first state, the fourth state, and the sixth state, the apparatus may not be in the second state, the third state, and/or the fifth state). According to some aspects, the second state, the third state, and the sixth state exist concurrently and exclusive of the first state, the fourth state, and the fifth state (i.e., the apparatus may be in the second state, the third states, and the sixth state simultaneously; however, if in the second state and the third state and the sixth state, the apparatus may not be in the first state, the fourth state, and/or the fifth state). According to some aspects, the first state, the fourth state, and the fifth state exist concurrently and exclusive of the second state, the third state, and the sixth state (i.e., the apparatus may be in the first state, the fourth state, and the fifth state simultaneously; however, if in the first state, the fourth state, and the fifth state, the apparatus may not be in the second state, the third state, and/or the sixth state).

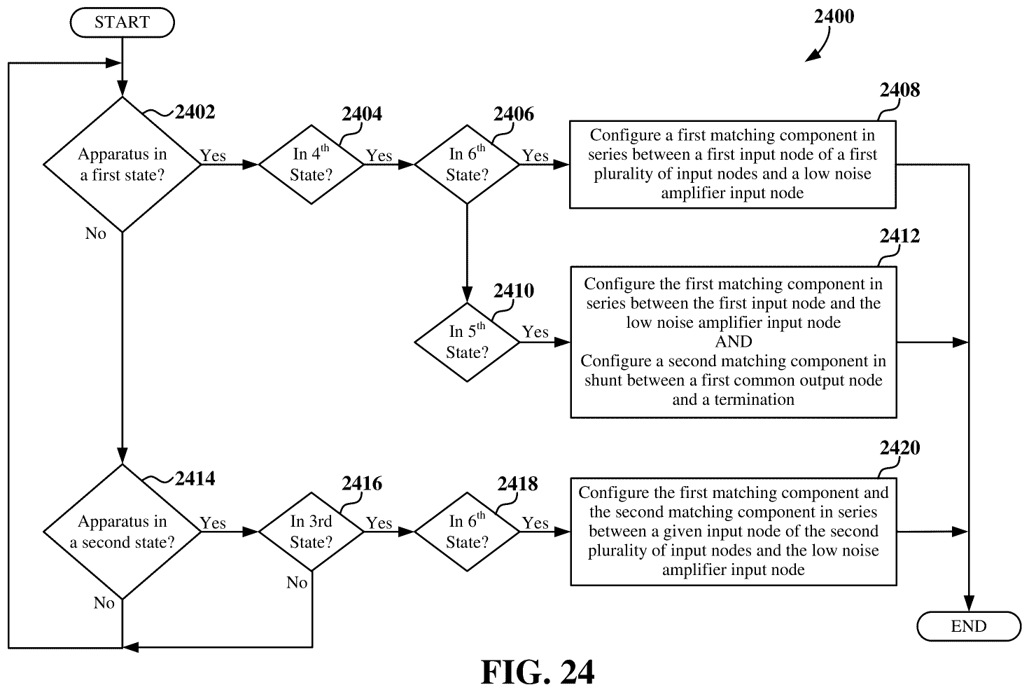

FIG. 24 is a flow chart illustrating an example process 2400 (e.g., a method) at an apparatus (e.g., a scheduled entity, a user equipment, a wireless communications device, a mobile communication device) according to some aspects of the disclosure. As described below, some or all illustrated features may be omitted in a particular implementation within the scope of the present disclosure, and some illustrated features may not be required for the implementation of all examples. In some examples, the process 2400 may be carried out by the apparatus 2200, as shown and described in connection with FIG. 22. The apparatus 2200 may be similar to, for example, any of the scheduled entities, user equipment, wireless communications devices, and/or mobile communication devices as shown and described in connection with FIG. 1. In some examples, the process 2400 may be carried out by any suitable apparatus or means for carrying out the functions or algorithm described below.

At block 2402, the apparatus may determine if it is in (or is being commanded to enter) a first state. For example, the matching network state selection circuitry as shown and described in connection with FIG. 22 may provide a means for determining if the apparatus is in (or is being commanded to enter) the first state.

At block 2404, in response to determining that the apparatus is in (or is being commanded to enter) the first state, the apparatus may determine if it is in (or is being commanded to enter) a fourth state. For example, the matching network state selection circuitry as shown and described in connection with FIG. 22 may provide a means for determining if the apparatus is in (or is being commanded to enter) the fourth state.

At block 2406, in response to determining that the apparatus is in (or is being commanded to enter) the fourth state, the apparatus may determine if it is in (or is being commanded to enter) a sixth state. For example, the matching network state selection circuitry as shown and described in connection with FIG. 22 may provide a means for determining if the apparatus is in (or is being commanded to enter) the sixth state.

At block 2408, in response to determining that the apparatus is in (or is being commanded to enter) the sixth state, the apparatus may configure a first matching component in series between the first input node of the first plurality of input nodes and the low noise amplifier input node. For example, the matching network state selection circuitry as shown and described in connection with FIG. 22 may provide a means for configuring a first matching component in series between the first input node of the first plurality of input nodes and the low noise amplifier input node. Thereafter, the process may end.

Returning to block 2406, in response to determining that the apparatus is not in (or is not being commanded to enter) the sixth state, the process may advance to block 2410.

At block 2410, in response to determining that the apparatus is not in (or is not being commanded to enter) the sixth state, the apparatus may determine if it is in (or is being commanded to enter) a fifth state. For example, the matching network state selection circuitry as shown and described in connection with FIG. 22 may provide a means for determining if the apparatus is in (or is being commanded to enter) the fifth state.

At block 2412, in response to determining that the apparatus is in (or is being commanded to enter) the fifth state, the apparatus may configure a first matching component in series between the first input node and the low noise amplifier input node and may configure a second matching component in shunt between a first common output node and a termination. For example, the matching network state selection circuitry as shown and described in connection with FIG. 22 may provide a means for configuring the first matching component in series between the first input node and the low noise amplifier input node and a means for configuring a second matching component in shunt between a first common output node and a termination. Thereafter, the process may end.

Returning to block 2402, in response to determining that the apparatus is not in (or is not being commanded to enter) the first state, the process may advance to block 2414.

At block 2414, the apparatus may determine if it is in (or is being commanded to enter) a second state. For example, the matching network state selection circuitry as shown and described in connection with FIG. 22 may provide a means for determining if the apparatus is in (or is being commanded to enter) the second state.

At block 2414, in response to determining that the apparatus is not in (or is not being commanded to enter) the second state, the process may return to block 2402; however, in response to determining that the apparatus is in (or is being commanded to enter) the second state, the process may advance to block 2416.

At block 2416, in response to determining that the apparatus is in (or is being commanded to enter) the second state, the apparatus may determine if it is in (or is being commanded to enter) a third state. For example, the matching network state selection circuitry as shown and described in connection with FIG. 22 may provide a means for determining if the apparatus is in (or is being commanded to enter) the third state.

At block 2418, in response to determining that the apparatus is in (or is being commanded to enter) the third state, the apparatus may determine if it is in (or is being commanded to enter) the sixth state. For example, the matching network state selection circuitry as shown and described in connection with FIG. 22 may provide a means for determining if the apparatus is in (or is being commanded to enter) the sixth state.

At block 2420, in response to determining that the apparatus is in (or is being commanded to enter) the sixth state, the apparatus may configure the first matching component and the second matching component in series between a given input node of the second plurality of input nodes and the low noise amplifier input node. For example, the matching network state selection circuitry as shown and described in connection with FIG. 22 may provide a means for configuring the first matching component and the second matching component in series between a given input node of the second plurality of input nodes and the low noise amplifier input node. Thereafter, the process may end.

According to some aspects, the process 2400 may include configuring a first series matching network between the first common output node and a low noise amplifier in response to configuring the apparatus in the first state and the fourth state concurrently, configuring a second series matching network between the second common output node and the low noise amplifier in response to configuring the apparatus in the second state and the third state concurrently, and configuring a shunt-series matching network between the first common output node and the low noise amplifier in response to configuring the apparatus in the first state and the fourth state concurrently.

For example, the matching network state selection circuitry may provide a means for configuring a first series matching network between the first common output node and a low noise amplifier in response to configuring the apparatus in the first state and the fourth state concurrently, configuring a shunt-series matching network between the first common output node and the low noise amplifier in response to configuring the apparatus in the first state and the fifth state concurrently, and configuring a second series matching network between the second common output node and the low noise amplifier in response to configuring the apparatus in the second state and the third state concurrently.

According to some aspects, the first plurality of switches may be a first demultiplexer, and the second plurality of switches may be a second demultiplexer. Both the first demultiplexer and the second demultiplexer may be included in a preselector, for example.

In accordance with various aspects of the disclosure, an element, or any portion of an element, or any combination of elements may be implemented with a processing system 2201 that includes one or more processors, generally represented by processor 2204. The one or more processors (generally represented by processor 2204), as utilized in the apparatus 2200, may be configured to, individually or collectively, implement any one or more of the methods or processes described herein and/or illustrated, for example, in FIGS. 1, 2, 4, 5, 7, 9, 11, 12, 13, 14, 15A, 15B, 16A, 16B, 16C, 21A, 21B, 21C, 22, 23, and 24.

Of course, in the above examples, the circuitry included in the one or more processors (generally represented by processor 2204) of FIG. 22 is merely provided as an example. Other means for carrying out the described processes or functions may be included within various aspects of the present disclosure, including but not limited to the instructions stored in the computer-readable medium 2206 of FIG. 22 or any other suitable apparatus or means described in association with any one of the FIGS. 1, 2, 4, 5, 7, 9, 11, 12, 13, 14, 15A, 15B, 16A, 16B, 16C, 21A, 21B, 21C, 22, 23, and 24 utilizing, for example, the processes and/or algorithms described herein in relation to any of the preceding figures and/or FIGS. 23 and/or 24.

The following provides an overview of aspects of the present disclosure:

Aspect 1: An apparatus, comprising: a first plurality of switches having a respective first plurality of input nodes and a first common output node; a second plurality of switches having a respective second plurality of input nodes and a second common output node; a low noise amplifier having a low noise amplifier input node and a low noise amplifier output node; a first matching component having a first node coupled to the first common output node and having a second node coupled to the low noise amplifier input node; and a second matching component having a third node coupled to the second common output node and having fourth node coupled to the first common output node and the first node, wherein at least two matching network configurations of the first matching component and the second matching component are obtained by configuring respective states of the first plurality of switches and the second plurality of switches.

Aspect 2: The apparatus of aspect 1, further comprising: a first plurality of radio frequency (RF) filters respectively coupled to the first plurality of input nodes; and a second plurality of radio frequency (RF) filters respectively coupled to the second plurality of input nodes.

Aspect 3: The apparatus of aspect 1 or aspect 2, wherein: the first matching component is a first inductor having a first value of inductance; and the second matching component is a second inductor having a second value of inductance, wherein the first value of inductance and the second value of inductance are greater than zero and the first value is greater than, equal to, or less than the second value.

Aspect 4: The apparatus of any of aspects 1 through 3, wherein: a first switch of the first plurality of switches corresponding to a first input node of the first plurality of input nodes is configured in a closed state and remaining switches of the first plurality of switches are each configured in an open state; each of the second plurality of switches is configured in an open state and collectively presents an open circuit to the third node of the second matching component; and a matching network of the apparatus corresponds to the first matching component coupled in series between: the first input node of the first plurality of input nodes, and the low noise amplifier input node.

Aspect 5: The apparatus of any of aspects 1 through 4, wherein: each of the first plurality of switches is configured in an open state and collectively present an open circuit to the first node of the first matching component and the fourth node of the second matching component; a first switch of the second plurality of switches corresponding to a first input node of the second plurality of input nodes is configured in a closed state and each remaining switch of the second plurality of switches is configured in an open state; and a matching network of the apparatus corresponds to a series combination of the first matching component and the second matching component coupled between: the first input node of the second plurality of input nodes, and the low noise amplifier input node.

Aspect 6: The apparatus of any of aspects 1 through 5, further comprising at least one of: a first switch coupled between the first common output node and a node shared by the first node of the first matching component and the fourth node of the second matching component, a second switch coupled between the second common output node and the third node of the second matching component, or a third switch coupled between the fourth node of the second matching component and the node shared by the first node of the first matching component and the fourth node of the second matching component.

Aspect 7: The apparatus of any of aspects 1 through 6, further comprising: a termination; and a termination switch configured to present an open circuit at the second common output node or a short circuit to the termination at the second common output node.

Aspect 8: The apparatus of aspect 7, wherein the termination switch is integral to the second plurality of switches, and the termination is external to the second plurality of switches or integral with the second plurality of switches.

Aspect 9: The apparatus of any of aspects 1 through 8, wherein the apparatus is configured to present one of a plurality of matching network configurations to the low noise amplifier input node based on respective states of the first plurality of switches, the second plurality of switches, and the termination switch.

Aspect 10: The apparatus of any of aspects 1 through 9, wherein: a first switch of the first plurality of switches is configured in a closed state; each remaining switch of the first plurality of switches is configured in an open state; each switch of the second plurality of switches is configured in an open state; the termination switch is configured in a closed state; and a matching network of the apparatus corresponds to: the second matching component, coupled in shunt between: a shared node, the shared node comprising the first common output node, the fourth node of the second matching component, and the first node of the first matching component, and the termination via the termination switch coupled between the third node of the second matching component and the termination; and the first matching component coupled in series between the shared node and the input node of the low noise amplifier.

Aspect 11. The apparatus of any of aspects 1 through 10, wherein the apparatus is configured to present one of a plurality of matching network configurations to the low noise amplifier input node based on respective states of the first plurality of switches and the second plurality of switches.

Aspect 12. The apparatus of aspect 11, wherein the plurality of matching network configurations comprises: a first series matching network; and a second series matching network configured differently from the first series matching network.

Aspect 13. The apparatus of 12, wherein: the first series matching network comprises the first matching component coupled at the first node to the first common output node and at the second node to the low noise amplifier input node; and the second series matching network comprises: the first matching component coupled at the second node to the low noise amplifier input node and at the first node to the fourth node of the second matching component, and the second matching component coupled at the fourth node to the first node of the first matching component and at the third node to the second common output node.

Aspect 14. The apparatus of any of aspects 1 through 13, further comprising: a control circuit configured to output a control signal to configure a respective state of each of the first plurality of switches, the second plurality of switches, and the termination switch.

Aspect 15: The apparatus of any of aspects 1 through 14, further comprising at least: a first bandpass filter having a first center frequency and a first bandwidth coupled to a first input node of the first plurality of input nodes of the first plurality of switches; and a second bandpass filter having a second center frequency, lower than the first center frequency, and a second bandwidth coupled to a second input node of the second plurality of input nodes of the second plurality of switches, wherein, based on respective states of the first plurality of switches and the second plurality of switches, the apparatus is configured to: match a first output impedance of the first bandpass filter as seen at the first common output node to an input impedance of the low noise amplifier at the first center frequency and the first bandwidth via a first series matching network, the first series matching network comprising the first matching component in series between the first input node and the low noise amplifier input node, and match a second output impedance of the third bandpass filter as seen at the second common output node to the input impedance of the low noise amplifier at the second center frequency and the second bandwidth via a second series matching network, the second series matching network comprising a series combination of the first matching component and the second matching component in series between the second input node of the second plurality of input nodes, and the low noise amplifier input node.

Aspect 16. The apparatus of aspect 7 or any of aspects 8 through 15, wherein the apparatus is configured to present one of a plurality of matching network configurations to the low noise amplifier input node based on respective states of the first plurality of switches, the second plurality of switches, and the termination switch.

Aspect 17. The apparatus of 16, wherein the plurality of matching network configurations comprises: a first series matching network; a shunt-series matching network; and a second series matching network configured differently from the first series matching network.

Aspect 18. The apparatus of 17, wherein: the first series matching network comprises the first matching component coupled at the first node to the first common output node and at the second node to the low noise amplifier input node; the shunt-series matching network comprises: the first matching component coupled at the first node to the first common output node and at the second node to the low noise amplifier input node, and the second matching component coupled: at the fourth node to the first node of the first matching component and the first common output node, and at the third node to the termination via the termination switch; and the second series matching network comprises: the first matching component coupled at the second node to the low noise amplifier input node and at the first node to the fourth node of the second matching component, and the second matching component coupled at the fourth node to the first node of the first matching component and at the third node to the second common output node.

Aspect 19. The apparatus of any of aspects 1 through 18, further comprising at least: a first bandpass filter having a first center frequency coupled to a first input node of the first plurality of switches; a second bandpass filter having a second center frequency, lower than the first center frequency, coupled to a second input node of the first plurality of switches; and a third bandpass filter having a third center frequency, lower than the second center frequency, coupled to a given input node of the second plurality of switches, wherein, based on respective states of the first plurality of switches, the second plurality of switches, and the termination switch, the apparatus is respectively configured to: match a first output impedance of the first bandpass filter as seen at the first common output node to an input impedance of the low noise amplifier via a first series inductance matching network, match a second output impedance of the second bandpass filter as seen at the first common output node to the input impedance of the low noise amplifier via a series inductance-shunt inductance matching network, and match a third output impedance of the third bandpass filter as seen at the second common output node to the input impedance of the low noise amplifier via a second series inductance matching network, the second series inductance matching network comprising a series combination of the first matching component and the second matching component.

Aspect 20. The apparatus of any of aspects 1 through 19, wherein the first plurality of switches is located in a first preselector switch matrix, and the second plurality of switches and the termination switch are located in a second preselector switch matrix.

Aspect 21. The apparatus of any of aspects 1 through 20, wherein the first plurality of switches is configured as a first demultiplexer of a preselector, and the second plurality of switches is configured as a second demultiplexer of the preselector.

Aspect 22: An apparatus, comprising: a first plurality of switches having a respective first plurality of input nodes and a first common output node; a second plurality of switches having a respective second plurality of input nodes and a second common output node; a termination switch, different from any of the first plurality of switches and the second plurality of switches, coupled to the second common output node and selectively coupled to a ground termination; at least one additional plurality of switches having a respective at least one additional plurality of input nodes and an at least one additional common output node; at least one additional termination switch, different from any of the first plurality of switches, the second plurality of switches, the termination switch, and the at least one additional plurality of switches, coupled to the at least one additional common output node and selectively coupled to the ground termination; a low noise amplifier having a low noise amplifier input node and a low noise amplifier output node; a first matching component coupled at a first node to the first common output node and at a second node to the low noise amplifier input node; a second matching component coupled at a third node to the second common output node and at a fourth node to the first common output node and the first node; and at least one additional matching component coupled at a fifth node to the at least one additional common output node and at a sixth node to the second common output node.

Aspect 23: The apparatus of aspect 22, wherein: the termination switch is configured to present at least one of: an open circuit to the second common output node, or a short circuit to a ground to the second common output node, and the at least one additional termination switch is configured to present at least one of: an additional open circuit to the at least one additional common output node, or an additional short circuit to the ground to the at least one additional common output node.

Aspect 24: The apparatus of aspect 22 or 23, further comprising: a control circuit configured to output a control signal to configure a respective state of each of the first plurality of switches, the second plurality of switches, the termination switch, the at least one additional plurality of switches, and the at least one additional termination switch.

Aspect 25: The apparatus of any of aspects 22 through 24, wherein: the first matching component is a series inductor coupled between the low noise amplifier input node and the one of the first plurality of input nodes; the second matching component is terminated with a first open circuit at the third node; and the at least one additional matching component is terminated with a second open circuit at the fifth node.

Aspect 26: The apparatus of any of aspects 22 through 25, wherein: the first matching component is a first series inductor coupled at the second node to the low noise amplifier input node and at the first node to the fourth node of the second matching component; the second matching component is a second series inductor coupled at the fourth node to the first node of the first matching component and at the third node to the one of the second plurality of input nodes via one of the second plurality of switches; and the at least one additional matching component is terminated with an open circuit at the fifth node.

Aspect 27: The apparatus of any of aspects 22 through 26, wherein: the first matching component is a first series inductor coupled at the second node to the low noise amplifier input node and at the first node to the fourth node of the second matching component; the second matching component is a second series inductor coupled at the fourth node to the first node of the first matching component and at the third node to the sixth node of the at least one additional matching component; the at least one additional matching component is a third series inductor coupled at the sixth node to the third node of the second matching component and at the fifth node to the one of the at least one additional plurality of input nodes via one of the at least one additional plurality of switches.

Aspect 28: The apparatus of any of aspects 22 through 27, wherein the apparatus is configured to present one of a plurality of matching network configurations to the low noise amplifier input node based on respective states of the first plurality of switches, the second plurality of switches, the termination switch, the at least one additional plurality of switches, and the at least one additional termination switch.

Aspect 29: The apparatus of aspect 28, wherein the plurality of matching network configurations comprises: a first series matching network; a second series matching network configured differently from the first series matching network; and a third series matching network configured differently from the first series matching network and the second series matching network, wherein a first value of impedance of the first series matching network is less than a second value of impedance of the second series matching network, and the second value of impedance of the second series matching network is less than a third value of impedance of the third series matching network.

Aspect 30: The apparatus of any of aspects 22 through 29, further comprising at least: a first bandpass filter having a first center frequency coupled to a first input node of the first plurality of switches; a second bandpass filter having a second center frequency, higher than the first center frequency, coupled to a second input node of the second plurality of switches; and a third bandpass filter having a third center frequency, higher than the second center frequency, coupled to a third input node of the at least one additional plurality of switches, wherein, based on respective states of the first plurality of switches, the second plurality of switches, the termination switch, the at least one additional plurality of switches, and the at least one additional termination switch, the apparatus is respectively configured to: match a first output impedance of the first bandpass filter as seen at the first common output node to an input impedance of the low noise amplifier via a first series inductance matching network, a first value of the first series inductance matching network comprising an inductance of the first matching component, match a second output impedance of the second bandpass filter as seen at the second common output node to the input impedance of the low noise amplifier via a second series inductance matching network, a second value of the second series inductance matching network comprising a first sum of inductances of the first matching component and the second matching component, and match a third output impedance of the third bandpass filter as seen at the at least one additional common output node to the input impedance of the low noise amplifier via a third series inductance matching network, a third value of the third series inductance matching network comprising a second sum of inductances of the first matching component, the second matching component, and the at least one additional matching component.

Aspect 31: The apparatus of any of aspects 22 through 30, wherein the first plurality of switches is configured as a first preselector switch matrix, the second plurality of switches and the termination switch are configured as a second preselector switch matrix, and the at least one additional plurality of switches and the at least one additional termination switch are configured as a third preselector switch matrix.

Aspect 32: The apparatus of any of aspects 22 through 31, wherein the first plurality of switches is configured as a first demultiplexer, the second plurality of switches and the termination switch are configured as a second demultiplexer, and the at least one additional plurality of switches and the at least one additional termination switch are configured as a third demultiplexer.

Aspect 33: A method at an apparatus, comprising: configuring a first plurality of switches coupled between respective ones of a first plurality of input nodes and a first common output node to either: a first state in which a first switch of the first plurality of switches is closed and remaining switches of the first plurality of switches are open, or a second state in which each of the first plurality of switches are open; and configuring a second plurality of switches coupled between respective ones of a second plurality of input nodes and a second common output node to either: a third state in which a second switch of the second plurality of switches is closed and remaining switches of the second plurality of switches are open, or a fourth state in which each of the second plurality of switches are open, and configuring a termination switch, coupled between the second common output node and a termination to either: a fifth state in which the termination switch is closed, or a sixth state in which the termination switch is open.

Aspect 34: The method of aspect 33, wherein: the first state, the fourth state, and the sixth state exist concurrently and exclusive of the second state, the third state, and the fifth state; the second state, the third state, and the sixth state exist concurrently and exclusive of the first state, the fourth state, and the fifth state; or the first state, the fourth state, and the fifth state exist concurrently and exclusive of the second state, the third state, and the sixth state.

Aspect 35: The method of aspect 33 or 34, further comprising: configuring a first matching component in series between a first input node of the first plurality of input nodes and a low noise amplifier input node in the first state, the fourth state, and the sixth state; configuring the first matching component and a second matching component in series between a given input node of the second plurality of input nodes and the low noise amplifier input node in the second state, the third state, and the sixth state; and configuring the first matching component in series between the first input node and the low noise amplifier input node, and configuring the second matching component in shunt between the first common output node and the termination in the first state, the fourth state, and the fifth state.

Aspect 36: The method of any of aspects 33 through 35, further comprising: configuring a first series matching network between the first common output node and a low noise amplifier in response to configuring the apparatus in the first state and the fourth state concurrently; configuring a shunt-series matching network between the first common output node and the low noise amplifier in response to configuring the apparatus in the first state, the fourth state, and the fifth state concurrently; and configuring a second series matching network between the second common output node and the low noise amplifier in response to configuring the apparatus in the second state and the third state concurrently.

Aspect 37: The method of any of aspects 33 through 36, wherein the first plurality of switches is a first demultiplexer, and the second plurality of switches is a second demultiplexer.

Aspect 38: An apparatus, comprising: means for configuring a first plurality of switches coupled between respective ones of a first plurality of input nodes and a first common output node to either: a first state in which a first switch of the first plurality of switches is closed and remaining switches of the first plurality of switches are open, or a second state in which each of the first plurality of switches are open; and means for configuring a second plurality of switches coupled between respective ones of a second plurality of input nodes and a second common output node to either: a third state in which a second switch of the second plurality of switches is closed and remaining switches of the second plurality of switches are open, or a fourth state in which each of the second plurality of switches are open, and means for configuring a termination switch, coupled between the second common output node and a termination to either: a fifth state in which the termination switch is closed, or a sixth state in which the termination switch is open.

Aspect 39: The apparatus of aspect 38, wherein: the first state, the fourth state, and the sixth state exist concurrently and exclusive of the second state, the third state, and the fifth state; the second state, the third state, and the sixth state exist concurrently and exclusive of the first state, the fourth state, and the fifth state; or the first state, the fourth state, and the fifth state exist concurrently and exclusive of the second state, the third state, and the sixth state.

Aspect 40: The apparatus of aspect 38 or 39, further comprising: means for configuring a first matching component in series between a first input node of the first plurality of input nodes and a low noise amplifier input node in the first state, the fourth state, and the sixth state; means for configuring the first matching component and a second matching component in series between a given input node of the second plurality of input nodes and the low noise amplifier input node in the second state, the third state, and the sixth state; and means for configuring the first matching component in series between the first input node and the low noise amplifier input node, and configuring the second matching component in shunt between the first common output node and the termination in the first state, the fourth state, and the fifth state.

Aspect 41: The apparatus of any of aspects 38 through 40, further comprising: means for configuring a first series matching network between the first common output node and a low noise amplifier in response to configuring the apparatus in the first state and the fourth state concurrently; means for configuring a shunt-series matching network between the first common output node and the low noise amplifier in response to configuring the apparatus in the first state and the fifth state concurrently; and means for configuring a second series matching network between the second common output node and the low noise amplifier in response to configuring the apparatus in the second state and the third state concurrently.

Aspect 42: The apparatus of any of aspects 38 through 41, wherein the first plurality of switches is a first demultiplexer, and the second plurality of switches is a second demultiplexer.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed:

1. An apparatus, comprising:
a first plurality of switches having a respective first plurality of input nodes and a first common output node;
a second plurality of switches having a respective second plurality of input nodes and a second common output node;
a low noise amplifier having a low noise amplifier input node and a low noise amplifier output node;
a first matching component having a first node coupled to the first common output node and having a second node coupled to the low noise amplifier input node; and
a second matching component having a third node coupled to the second common output node and having fourth node coupled to the first common output node and the first node,
wherein at least two matching network configurations of the first matching component and the second matching component are obtained by configuring respective states of the first plurality of switches and the second plurality of switches.

2. The apparatus of claim 1, further comprising:
a first plurality of radio frequency (RF) filters respectively coupled to the first plurality of input nodes; and
a second plurality of radio frequency (RF) filters respectively coupled to the second plurality of input nodes.

3. The apparatus of claim 1, wherein:
the first matching component is a first inductor having a first value of inductance; and
the second matching component is a second inductor having a second value of inductance, wherein the first value of inductance and the second value of inductance are greater than zero and the first value of inductance is greater than, equal to, or less than the second value of inductance.

4. The apparatus of claim 1, wherein:
a first switch of the first plurality of switches corresponding to a first input node of the first plurality of input nodes is configured in a closed state and remaining switches of the first plurality of switches are each configured in an open state;
each of the second plurality of switches is configured in the open state and collectively presents an open circuit to the third node of the second matching component; and
a matching network of the apparatus corresponds to the first matching component coupled in series between:
the first input node of the first plurality of input nodes, and
the low noise amplifier input node.

5. The apparatus of claim 1, wherein:
each of the first plurality of switches is configured in an open state and collectively present an open circuit to the first node of the first matching component and the fourth node of the second matching component;
a first switch of the second plurality of switches corresponding to a first input node of the second plurality of input nodes is configured in a closed state and each remaining switch of the second plurality of switches is configured in the open state; and
a matching network of the apparatus corresponds to a series combination of the first matching component and the second matching component coupled between:
the first input node of the second plurality of input nodes, and
the low noise amplifier input node.

6. The apparatus of claim 1, further comprising at least one of:
a first switch coupled between the first common output node and a node shared by the first node of the first matching component and the fourth node of the second matching component;
a second switch coupled between the second common output node and the third node of the second matching component; or
a third switch coupled between the fourth node of the second matching component and the node shared by the first node of the first matching component and the fourth node of the second matching component.

7. The apparatus of claim 1, further comprising:
a termination; and
a termination switch configured to present an open circuit at the second common output node or a short circuit to the termination at the second common output node.

8. The apparatus of claim 7, wherein
the termination switch is integral to the second plurality of switches, and
the termination is external to the second plurality of switches or integral with the second plurality of switches.

9. The apparatus of claim 7, wherein the apparatus is configured to present one of a plurality of matching network configurations to the low noise amplifier input node based on respective states of the first plurality of switches, the second plurality of switches, and the termination switch.

10. The apparatus of claim 7, wherein:
a first switch of the first plurality of switches is configured in a closed state;
each remaining switch of the first plurality of switches is configured in an open state;
each switch of the second plurality of switches is configured in the open state; the termination switch is configured in the closed state; and
a matching network of the apparatus corresponds to:
the second matching component, coupled in shunt between:
a shared node, the shared node comprising the first common output node, the fourth node of the second matching component, and the first node of the first matching component, and
the termination via the termination switch coupled between the third node of the second matching component and the termination; and
the first matching component coupled in series between the shared node and the low noise amplifier input node.

11. A method at an apparatus, comprising:
configuring a first plurality of switches coupled between respective ones of a first plurality of input nodes and a first common output node to either:
a first state in which a first switch of the first plurality of switches is closed and remaining switches of the first plurality of switches are open, or
a second state in which each of the first plurality of switches are open;
configuring a second plurality of switches coupled between respective ones of a second plurality of input nodes and a second common output node to either:
a third state in which a second switch of the second plurality of switches is closed and remaining switches of the second plurality of switches are open, or
a fourth state in which each of the second plurality of switches are open; and
configuring a termination switch, coupled between the second common output node and a termination to either:
a fifth state in which the termination switch is closed, or
a sixth state in which the termination switch is open.

12. The method of claim 11, wherein:
the first state, the fourth state, and the sixth state exist concurrently and exclusive of the second state, the third state, and the fifth state;
the second state, the third state, and the sixth state exist concurrently and exclusive of the first state, the fourth state, and the fifth state; and
the first state, the fourth state, and the fifth state exist concurrently and exclusive of the second state, the third state, and the sixth state.

13. The method of claim 11, further comprising:
configuring a first matching component in series between a first input node of the first plurality of input nodes and a low noise amplifier input node in the first state, the fourth state, and the sixth state;
configuring the first matching component and a second matching component in series between a given input node of the second plurality of input nodes and the low noise amplifier input node in the second state, the third state, and the sixth state; and
configuring the first matching component in series between the first input node and the low noise amplifier input node, and configuring the second matching component in shunt between the first common output node and the termination in the first state, the fourth state, and the fifth state.

14. The method of claim 11, further comprising:
configuring a first series matching network between the first common output node and a low noise amplifier in response to configuring the apparatus in the first state and the fourth state concurrently;
configuring a shunt-series matching network between the first common output node and the low noise amplifier in response to configuring the apparatus in the first state, the fourth state, and the fifth state concurrently; and
configuring a second series matching network between the second common output node and the low noise amplifier in response to configuring the apparatus in the second state and the third state concurrently.

15. The method of claim 11, wherein the first plurality of switches is a first demultiplexer, and the second plurality of switches is a second demultiplexer.

16. An apparatus, comprising:
means for configuring a first plurality of switches coupled between respective ones of a first plurality of input nodes and a first common output node to either:
a first state in which a first switch of the first plurality of switches is closed and remaining switches of the first plurality of switches are open, or
a second state in which each of the first plurality of switches are open;
means for configuring a second plurality of switches coupled between respective ones of a second plurality of input nodes and a second common output node to either:
a third state in which a second switch of the second plurality of switches is closed and remaining switches of the second plurality of switches are open, or
a fourth state in which each of the second plurality of switches are open; and
means for configuring a termination switch, coupled between the second common output node and a termination to either:
a fifth state in which the termination switch is closed, or
a sixth state in which the termination switch is open.

17. The apparatus of claim 16, wherein:
the first state, the fourth state, and the sixth state exist concurrently and exclusive of the second state, the third state, and the fifth state;
the second state, the third state, and the sixth state exist concurrently and exclusive of the first state, the fourth state, and the fifth state; and
the first state, the fourth state, and the fifth state exist concurrently and exclusive of the second state, the third state, and the sixth state.

18. The apparatus of claim 16, further comprising:
means for configuring a first matching component in series between a first input node of the first plurality of input nodes and a low noise amplifier input node in the first state, the fourth state, and the sixth state;
means for configuring the first matching component and a second matching component in series between a given input node of the second plurality of input nodes and the low noise amplifier input node in the second state, the third state, and the sixth state; and
means for configuring the first matching component in series between the first input node and the low noise amplifier input node, and configuring the second matching component in shunt between the first common output node and the termination in the first state, the fourth state, and the fifth state.

19. The apparatus of claim 16, further comprising:
means for configuring a first series matching network between the first common output node and a low noise amplifier in response to configuring the apparatus in the first state and the fourth state concurrently;
means for configuring a shunt-series matching network between the first common output node and the low noise amplifier in response to configuring the apparatus in the first state and the fifth state concurrently; and
means for configuring a second series matching network between the second common output node and the low noise amplifier in response to configuring the apparatus in the second state and the third state concurrently.

20. The apparatus of claim 16, wherein the first plurality of switches is a first demultiplexer, and the second plurality of switches is a second demultiplexer.
